(19) United States
(12) Patent Application Publication
(10) Pub. No.: US 2024/0081060 A1
(43) Pub. Date: Mar. 7, 2024

(54) SEMICONDUCTOR MEMORY DEVICE AND METHOD OF MANUFACTURING THE SAME

(71) Applicant: SK hynix Inc., Icheon-si Gyeonggi-do (KR)

(72) Inventors: Changhan Kim, Icheon-si Gyeonggi-do (KR); In Ku KANG, Icheon-si Gyeonggi-do (KR); Dong Hyoub KIM, Icheon-si Gyeonggi-do (KR)

(73) Assignee: SK hynix Inc., Icheon-si Gyeonggi-do (KR)

(21) Appl. No.: 18/112,384

(22) Filed: Feb. 21, 2023

(30) Foreign Application Priority Data
Sep. 1, 2022 (KR) 10-2022-0110436

(51) Int. Cl. H10B 43/27; H10B 41/27; H10B 80/00

(52) U.S. Cl. CPC H10B 43/27; H10B 41/27; H10B 80/00

(57) ABSTRACT

A semiconductor memory device, and a method of manufacturing the same, includes a gate stack including a plurality of gate patterns and a plurality of interlayer insulating layers alternately stacked with each other in a cell region, a source line disposed on the gate stack, and a channel plug passing through the gate stack and the source line in a vertical direction. The channel plug includes a backgate, a backgate insulating layer surrounding a sidewall of the backgate, a channel layer surrounding the sidewall of the backgate, and a memory layer surrounding a sidewall of the channel layer. The backgate insulating layer extends between the backgate and the source line.

### CROSS-REFERENCE TO RELATED APPLICATION

The present application claims priority under 35 U.S.C. § 119(a) to Korean patent application number 10-2022-0110436, filed on Sep. 1, 2022, in the Korean Intellectual Property Office, the entire disclosure of which is incorporated herein by reference.

### BACKGROUND

### 1. Technical Field

The present disclosure relates to an electronic device, and more particularly, to a semiconductor memory device of a vertical channel structure and a method of manufacturing the same.

### 2. Related Art

Recently, a paradigm for a computer environment has been transformed into ubiquitous computing, which enables a computer system to be used virtually anywhere at any time. Therefore, use of a portable electronic device such as a mobile phone, a digital camera, and a notebook computer is rapidly increasing. Such a portable electronic device generally uses a semiconductor memory system that uses a memory device, that is, a data storage device. The data storage device is used as a main storage device or an auxiliary storage device of the portable electronic device.

The data storage device using the semiconductor memory device has advantages in that stability and durability are excellent because there is no mechanical driver, an access speed of information is very fast, and power consumption is low. As an example of a memory system having such advantages, a data storage device includes a universal serial bus (USB) memory device, a memory card having various interfaces, a solid state drive (SSD), and the like.

A semiconductor memory device is generally classified as a volatile memory device or a nonvolatile memory device.

A write speed and a read speed of the nonvolatile memory device are relatively slow, however, the nonvolatile memory device maintains storage data even though power supply is cut off. Therefore, a nonvolatile memory device is used to store data to be maintained regardless of power supply. A nonvolatile memory device includes read only memory (ROM), mask ROM (MROM), programmable ROM (PROM), erasable programmable ROM (EPROM), electrically erasable programmable ROM (EEPROM), flash memory, phase change random access memory (PRAM), magnetic RAM (MRAM), resistive RAM (RRAM), ferroelectric RAM (FRAM), or the like. Flash memory is generally classified as NOR type or NAND type.

The semiconductor memory device includes memory cells capable of storing data. To improve an integration degree of the memory cells, a three-dimensional semiconductor memory device has been proposed.

The three-dimensional semiconductor memory device includes memory cells arranged in three dimensions. The integration degree of the three-dimensional semiconductor memory device may be improved as the number of stacks of the memory cells increases. As the number of stacks of the memory cells increases, a technology capable of improving structural stability of the three-dimensional semiconductor memory device is required.

### SUMMARY

An embodiment of the present disclosure provides a semiconductor memory device having a high vertical height and having an improved electrical characteristic, and a method of manufacturing the same.

According to an embodiment of the present disclosure, a semiconductor memory device includes a gate stack including a plurality of gate patterns and a plurality of interlayer insulating layers alternately stacked with each other in a cell region, a source line disposed on the gate stack, and a channel plug passing through the gate stack and the source line in a vertical direction. The channel plug includes a backgate, a backgate insulating layer surrounding a sidewall of the backgate, a channel layer surrounding the sidewall of the backgate, and a memory layer surrounding a sidewall of the channel layer. The backgate insulating layer extends between the backgate and the source line.

According to the present disclosure, a method of manufacturing a semiconductor memory device includes: sequentially stacking a protective layer, a first source layer, a sacrificial layer, and a second source layer in a cell region of a first substrate; forming a stack in which a plurality of first material layers and a plurality of second material layers are alternately stacked on the second source layer; forming a preliminary channel plug passing through the stack, the second source layer, and the sacrificial layer; forming a trench passing through the stack and the second source layer to expose the sacrificial layer; exposing a portion of a sidewall of the preliminary channel plug by removing the exposed sacrificial layer; forming a third source layer in a space from which the sacrificial layer is removed; and removing the plurality of second material layers exposed through the trench, and forming a plurality of gate patterns in a space from which the plurality of second material layers are removed. Forming the preliminary channel plug includes forming a hole passing through the stack, the second source layer, and the sacrificial layer; and sequentially forming a memory layer and a channel layer along a sidewall and a bottom surface of the hole, and then forming a backgate sacrificial layer in a central region of the hole.

According to the present disclosure, a method of manufacturing a semiconductor memory device includes: sequentially stacking a protective layer, a first source layer, a sacrificial layer, and a second source layer in a cell region of a first substrate; forming a stack in which a plurality of first material layers and a plurality of second material layers are alternately stacked on the second source layer; forming a channel plug passing through the stack, the second source layer, and the sacrificial layer; forming a trench passing through the stack and the second source layer to expose the sacrificial layer; exposing a portion of a sidewall of the channel plug by removing the exposed sacrificial layer; forming a third source layer in a space from which the sacrificial layer is removed; and removing the plurality of material layers exposed through the trench, and forming a plurality of gate patterns in a space from which the plurality of material layers are removed. Forming the channel plug includes forming a hole passing through the stack, the second source layer, and the sacrificial layer; and sequentially forming a memory layer, a channel layer, and a first backgate insulating layer along a sidewall and a bottom surface of the hole, and then forming a backgate in a central region of the hole.

According to an embodiment of the present disclosure, a semiconductor memory device includes: a gate stack including a plurality of gate patterns and a plurality of interlayer insulating layers alternately stacked with each other in a cell region and a slimming region; a source line disposed on the gate stack of the cell region; a sacrificial pattern including a first source layer, a sacrificial layer, and a second source layer disposed on the gate stack of the slimming region; a separation pattern separating the source line from the sacrificial pattern in a boundary region between the cell region and the slimming region; and a channel plug passing through the gate stack of the cell region and a backgate connection structure passing through the gate stack of the slimming region.

According to the present disclosure, a method of manufacturing a semiconductor memory device includes: sequentially stacking a protective layer, a first source layer, a sacrificial layer, and a second source layer in a cell region and a slimming region of a first substrate; forming an isolation structure passing through the first source layer, the sacrificial layer, and the second source layer at a boundary between the cell region and the slimming region; forming a stack in which a plurality of first material layers and a plurality of second material layers are alternately stacked with each other on the second source layer; forming a preliminary channel plug passing through the stack, the second source layer, and the sacrificial layer of the cell region, and forming a dummy channel plug passing through the stack, the second source layer, and the sacrificial layer of the slimming region; forming a trench passing through the stack and the second source layer of the cell region to expose the sacrificial layer; exposing a portion of a sidewall of the preliminary channel plug by removing the exposed sacrificial layer; forming a third source layer in a space from which the sacrificial layer is removed; and removing the plurality of second material layers exposed through the trench, and forming a plurality of gate patterns in a space from which the plurality of second material layers are removed. Forming the preliminary channel plug and the dummy channel plug includes: forming a hole and a dummy hole passing through the stack, the second source layer, and the sacrificial layer of the cell region and the slimming region; and sequentially forming a memory layer and a channel layer along a sidewall and a bottom surface of the hole and the dummy hole, and then forming a backgate sacrificial layer in a central region of the hole.

According to the present disclosure, a method of manufacturing a semiconductor memory device includes: sequentially stacking a protective layer, a first source layer, a sacrificial layer, and a second source layer in a cell region and a slimming region of a first substrate; forming an isolation structure passing through the first source layer, the sacrificial layer, and the second source layer at a boundary between the cell region and the slimming region; forming a stack in which a plurality of first material layers and a plurality of second material layers are alternately stacked with each other on the second source layer; forming a preliminary channel plug passing through the stack, the second source layer, and the sacrificial layer of the cell region, and forming a dummy channel plug passing through the stack, the second source layer, and the sacrificial layer of the slimming region; forming a trench passing through the stack and the second source layer of the cell region to expose the sacrificial layer and forming a dummy trench passing through the stack and the second source layer of the slimming region to expose the sacrificial layer; exposing a portion of a sidewall of the preliminary channel plug and a portion of a sidewall of the dummy channel plug by removing the sacrificial layer of the cell region exposed through the trench and the sacrificial layer of the slimming region exposed through the dummy trench; forming a source line in the cell region and a dummy source line in the slimming region by forming a third source layer in a space from which the sacrificial layer is removed; and removing the plurality of second material layers exposed through the trench and the dummy trench, and forming a plurality of gate patterns in a space from which the plurality of second material layers are removed. Forming the preliminary channel plug and the dummy channel plug includes: forming a hole and a dummy hole passing through the stack, the second source layer, and the sacrificial layer of the cell region and the slimming region; and sequentially forming a memory layer and a channel layer along a sidewall and a bottom surface of the hole and the dummy hole, and then forming a backgate sacrificial layer in a central region of the hole.

According to the present disclosure, a method of manufacturing a semiconductor memory device includes: sequentially stacking a protective layer, a first source layer, a sacrificial layer, and a second source layer in a cell region and a slimming region of a first substrate; forming an isolation structure passing through the first source layer, the sacrificial layer, and the second source layer at a boundary between the cell region and the slimming region; forming a stack in which a plurality of first material layers and a plurality of second material layers are alternately stacked with each other on the second source layer; forming a channel plug passing through the stack, the second source layer, and the sacrificial layer of the cell region, and forming a dummy channel plug passing through the stack, the second source layer, and the sacrificial layer of the slimming region; forming a trench passing through the stack and the second source layer of the cell region to expose the sacrificial layer and forming a dummy trench passing through the stack and the second source layer of the slimming region to expose the sacrificial layer; exposing a portion of a sidewall of the channel plug and a portion of a sidewall of the dummy channel plug by removing the sacrificial layer of the cell region exposed through the trench and the sacrificial layer of the slimming region exposed through the dummy trench; forming a source line in the cell region and a dummy source line in the slimming region by forming a third source layer in a space from which the sacrificial layer is removed; and removing the plurality of second material layers exposed through the trench and the dummy trench, and forming a plurality of gate patterns in a space from which the plurality of second material layers are removed. Forming the channel plug and the dummy channel plug includes: forming a hole and a dummy hole passing through the stack, the second source layer, and the sacrificial layer of the cell region and the slimming region; and sequentially forming a memory layer, a channel layer, and a first backgate insulating layer along a sidewall and a bottom surface of the hole and the dummy hole, and then forming a backgate in a central region of the hole.

According to the present disclosure, a method of manufacturing a semiconductor memory device includes: sequentially stacking a protective layer, a first source layer, a sacrificial layer, and a second source layer in a cell region and a slimming region of a first substrate; forming an isolation structure passing through the first source layer, the sacrificial layer, and the second source layer at a boundary between the cell region and the slimming region; forming a stack in which a plurality of first material layers and a plurality of second material layers are alternately stacked with each other on the second source layer; forming a preliminary channel plug passing through the stack, the second source layer, and the sacrificial layer of the cell region, and forming a dummy channel plug passing through the stack, the second source layer, and the sacrificial layer of the slimming region is formed; forming a trench passing through the stack and the second source layer of the cell region to expose the sacrificial layer; exposing a portion of a sidewall of the preliminary channel plug and a portion of a sidewall of the dummy channel plug by removing the sacrificial layer of the cell region and the sacrificial layer of the slimming region exposed through the trench; forming a source line in the cell region and a dummy source line in the slimming region by forming a third source layer in a space from which the sacrificial layer is removed; removing the plurality of second material layers exposed through the trench, and forming a plurality of gate patterns in a space from which the plurality of second material layers are removed; and forming a contact plug connected to the first source layer by passing through the dummy channel plug. Forming the preliminary channel plug and the dummy channel plug includes: forming a hole and a dummy hole passing through the stack, the second source layer, and the sacrificial layer of the cell region and the slimming region; and sequentially forming a memory layer and a channel layer along a sidewall and a bottom surface of the hole and the dummy hole, and then forming a backgate sacrificial layer in a central region of the hole.

According to the present disclosure, a method of manufacturing a semiconductor memory device includes: sequentially stacking a protective layer, a first source layer, a sacrificial layer, and a second source layer in a cell region and a slimming region of a first substrate; forming an isolation structure passing through the first source layer, the sacrificial layer, and the second source layer at a boundary between the cell region and the slimming region; forming a stack in which a plurality of first material layers and a plurality of second material layers are alternately stacked with each other on the second source layer; forming a channel plug passing through the stack, the second source layer, and the sacrificial layer of the cell region, and forming a dummy channel plug passing through the stack, the second source layer, and the sacrificial layer of the slimming region; forming a trench passing through the stack and the second source layer of the cell region to expose the sacrificial layer; exposing a portion of a sidewall of the channel plug by removing the sacrificial layer of the cell region exposed through the trench; forming a source line in the cell region by forming a third source layer in a space from which the sacrificial layer is removed; removing the plurality of second material layers exposed through the trench, and forming a plurality of gate patterns in a space from which the plurality of second material layers are removed; and forming a contact plug connected to the first source layer by passing through the dummy channel plug. Forming the channel plug and the dummy channel plug includes: forming a hole and a dummy hole passing through the stack, the second source layer, and the sacrificial layer of the cell region and the slimming region; and sequentially forming a memory layer, a channel layer, and a first backgate insulating layer along a sidewall and a bottom surface of the hole and the dummy hole, and then forming a backgate in a central region of the hole.

According to the present technology, a semiconductor memory device having a high vertical height and having an improved electrical characteristic may be formed. In addition, a backgate line connected to a backgate disposed in a central region of a vertical channel structure may be stably formed.

### BRIEF DESCRIPTION OF THE DRAWINGS

FIG. 1 is a block diagram illustrating a semiconductor memory device according to an embodiment of the present disclosure.

FIG. 2 is a block diagram illustrating a memory cell array of FIG. 1.

FIG. 3 is an equivalent circuit diagram illustrating a memory block of FIG. 2.

FIGS. 4A to 4E, 5, 6, and 7A to 7D are cross-sectional views illustrating a method of manufacturing a semiconductor memory device according to the present disclosure.

FIGS. 8A to 8C are cross-sectional views illustrating another method of manufacturing a semiconductor memory device according to the present disclosure.

FIGS. 9A to 9E are cross-sectional views illustrating another method of manufacturing a semiconductor memory device according to the present disclosure.

FIGS. 10A to 10C are cross-sectional views illustrating a method of manufacturing a semiconductor memory device according to the present disclosure.

FIGS. 11A to 11E, 12, and 13A to 13C are cross-sectional views illustrating another method of manufacturing a semiconductor memory device according to the present disclosure.

FIGS. 14A to 14D are cross-sectional views illustrating another method of manufacturing a semiconductor memory device according to the present disclosure.

FIGS. 15A to 15E are cross-sectional views illustrating another method of manufacturing a semiconductor memory device according to the present disclosure.

FIGS. 16A to 16E, 17, and 18A to 18C are cross-sectional views illustrating another method of manufacturing a semiconductor memory device according to the present disclosure.

FIGS. 19A and 19B are cross-sectional views illustrating another method of manufacturing a semiconductor memory device according to the present disclosure.

FIG. 20 is a block diagram illustrating a configuration of a memory system according to an embodiment of the present disclosure.

FIG. 21 is a block diagram illustrating a configuration of a computing system according to an embodiment.

### DETAILED DESCRIPTION

Specific structural or functional descriptions of embodiments according to the concept of the present disclosure which are disclosed in the present specification or application are illustrated only to describe the embodiments according to the concept of the present disclosure. The embodiments according to the concept of the present disclosure may be carried out in various forms and should not be construed as being limited to the embodiments described in the present specification or application.

Hereinafter, embodiments of the present disclosure will be described with reference to the accompanying drawings to describe in detail enough to allow those of ordinary skill in the art to implement the technical idea of the present disclosure.

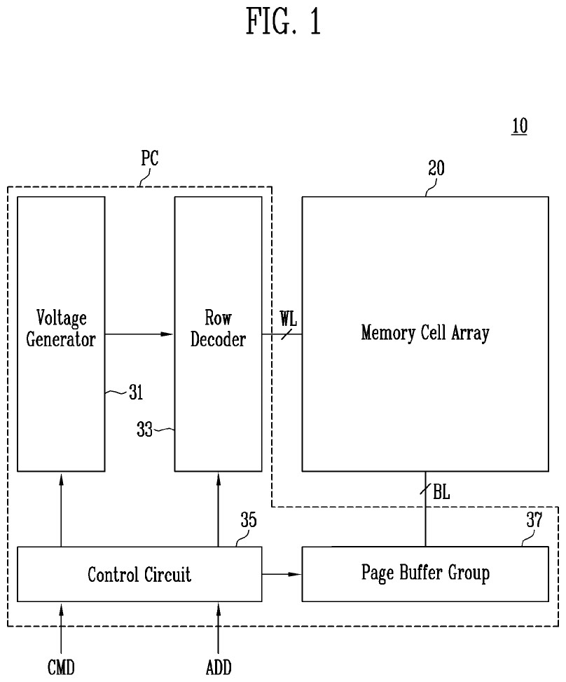

FIG. 1 is a block diagram illustrating a semiconductor memory device according to an embodiment of the present disclosure.

Referring to FIG. 1, the semiconductor memory device 10 includes a peripheral circuit PC and a memory cell array 20.

The peripheral circuit PC may be configured to control a program operation for storing data in the memory cell array 20, a read operation for outputting data stored in the memory cell array 20, and an erase operation for erasing data stored in the memory cell array 20.

As an embodiment, the peripheral circuit PC may include a voltage generator 31, a row decoder 33, a control circuit 35, and a page buffer group 37.

The memory cell array 20 may include a plurality of memory blocks. The memory cell array 20 may be connected to the row decoder 33 through word lines WL, and may be connected to the page buffer group 37 through bit lines BL.

The control circuit 35 may control the voltage generator 31, the row decoder 33, and the page buffer group 37 in response to a command CMD and an address ADD.

The voltage generator 31 may generate various operation voltages such as an erase voltage, a ground voltage, a program voltage, a verify voltage, a pass voltage, and a read voltage used for the program operation, the read operation, and the erase operation in response to control of the control logic 35.

The row decoder 33 may select a memory block in response to the control of the control circuit 35. The row decoder 33 may be configured to apply the operation voltages to the word lines WL connected to the selected memory block.

The page buffer group 37 may be connected to the memory cell array 20 through the bit lines BL. The page buffer group 37 may temporarily store data received from an input/output circuit (not shown) during the program operation in response to the control of the control circuit 35. The page buffer group 37 may sense a voltage or a current of the bit lines BL during the read operation or a verify operation in response to the control of the control circuit 35. The page buffer group 37 may select the bit lines BL in response to the control of the control circuit 35.

Structurally, the memory cell array 20 may overlap a portion of the peripheral circuit PC.

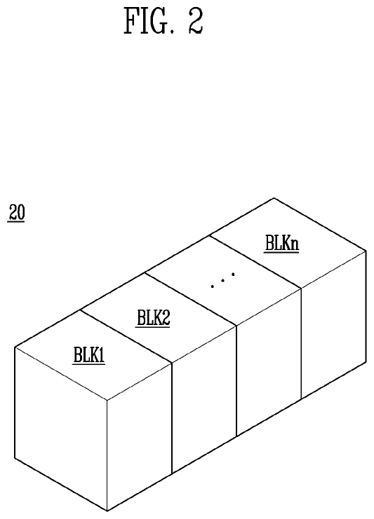

FIG. 2 is a block diagram illustrating the memory cell array of FIG. 1.

Referring to FIG. 2, the memory cell array 20 may include a plurality of memory blocks BLK1 to BLKn.

Each of the memory blocks BLK1 to BLKn may include a source line, bit lines, memory cell strings electrically connected to the source line and the bit lines, word lines electrically connected to the memory cell strings, and select lines electrically connected to the memory cell strings. Each of the memory cell strings may include memory cells and select transistors connected in series by a channel pattern. The select lines and the word lines may be used as gate electrodes of the select transistors and the memory cells.

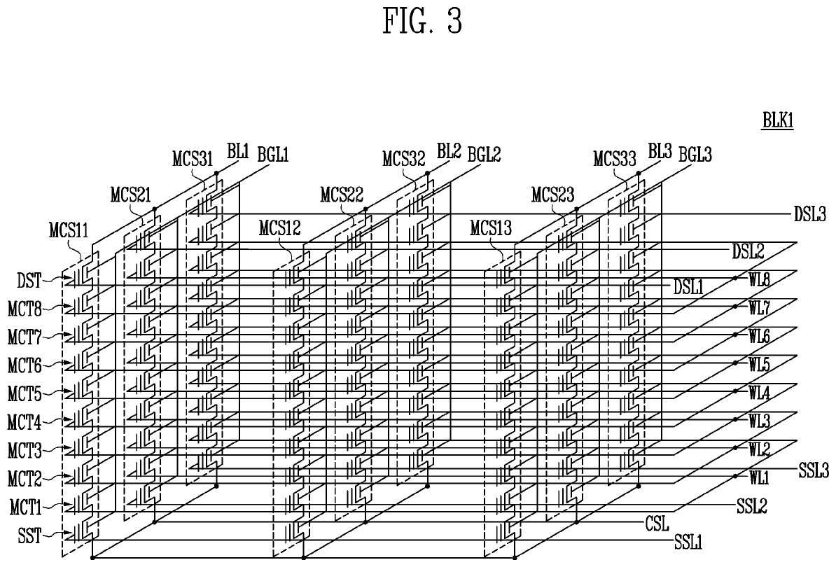

FIG. 3 is an equivalent circuit diagram illustrating the memory block of FIG. 2.

Referring to FIG. 3, the memory cell block BLK1 may include memory cell strings MCS11 to MCS33, word lines WL1 to WL8, drain select lines DSL1 to DSL3, source select lines SSL1 to SSL3, and a common source line CSL.

Memory cell strings MCS11, MCS21, and MCS31 are provided between a first bit line BL1, a first backgate line BGL1, and the common source line CSL, memory cell strings MCS12, MCS22, and MCS32 are provided between a second bit line BL2, a second backgate line BGL2, and the common source line CSL, and memory cell strings MCS13, MCS23, and MCS33 are provided between a third bit line BL3, a third backgate line BGL3, and the common source line CSL. Each of the memory cell strings (for example, MCS11) may include a drain select transistor DST, a plurality of memory cells MCT1 to MCT8, and a source select transistor SST connected in series.

The drain select transistor DST is connected to corresponding drain select lines DSL1 to DSL3. The plurality of memory cells MCT1 to MCT8 are connected to the corresponding word lines WL1 to WL8, respectively. The source select transistor SST is connected to corresponding source select lines SSL1 to SSL3. The drain select transistor DST is connected to the corresponding bit lines BL1 to BL3, and the source select transistor SST is connected to the common source line CSL.

In the present embodiment, the word line (for example, WL1) of the same height are commonly connected to each other, the drain select lines DSL1 to DSL3 are separated from each other, and the source select lines SSL1 to SSL3 are also separated from each other.

An operation of the memory cell strings shown in FIG. 3 is described as follows.

In a first step, to improve boosting efficiency of unselected memory cell strings except for a selected memory cell string (for example, MCS11), the source select transistor SST and the common source line CSL may be floated.

In a second step, the remaining word lines WL2 to WL8 except for the word line WL1 corresponding to the memory cell (for example, MCT1) to be programmed may be floated. At this time, a program voltage may be applied to the word line WL1 corresponding to the memory cell (for example, MCT1) to be programmed.

In a third step, a program operation may be performed on the target memory cell MCT1 by applying a voltage for a program operation to the first backgate line BGL1 corresponding to the selected memory cell string MCS11. In more detail, the target memory cell MCT1 may be selectively programmed by a program voltage applied to the word line WL1 corresponding to the memory cell (for example, MCT1) to be programmed, a program allowable voltage or a program inhibition voltage applied to the bit line BL1 of the selected memory cell string MCS11, and a pass voltage applied to the first backgate line BGL1.

In the above-described program operation, a disturb phenomenon due to the pass voltage applied to the unselected word lines may be prevented because the program operation is based on a method in which the pass voltage is applied to the backgate line rather than to the unselected word lines. In addition, because the disturb phenomenon is prevented, a program operation characteristic may be improved. Therefore, a cell characteristic and reliability may be improved, and a speed at which a channel is formed in a channel layer of a selected memory cell string may be improved.

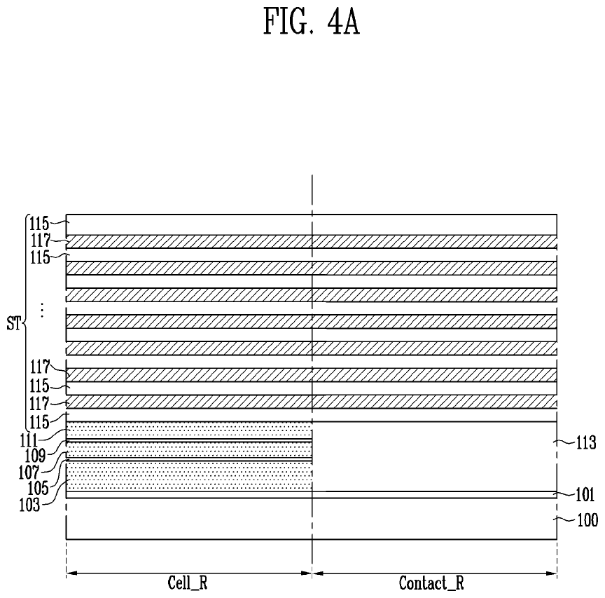

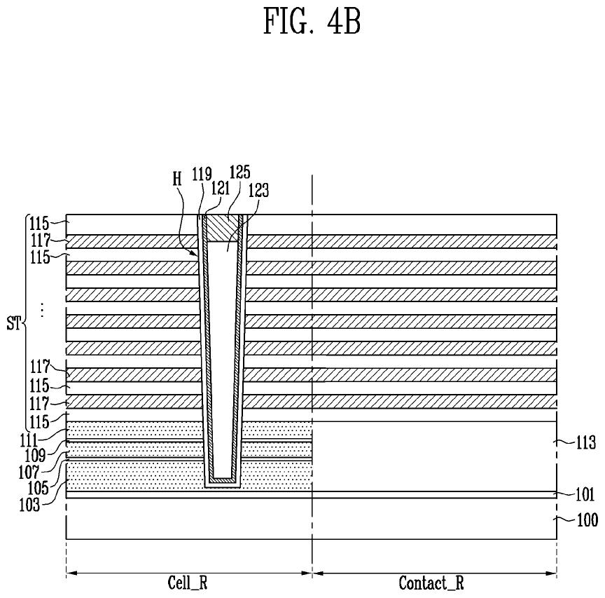

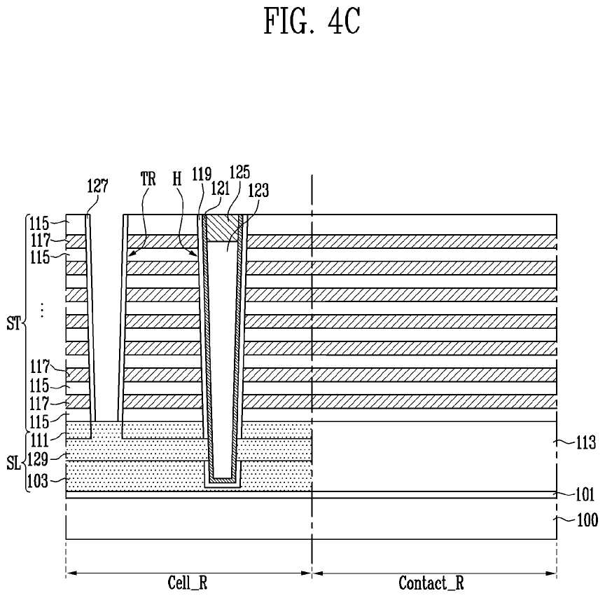

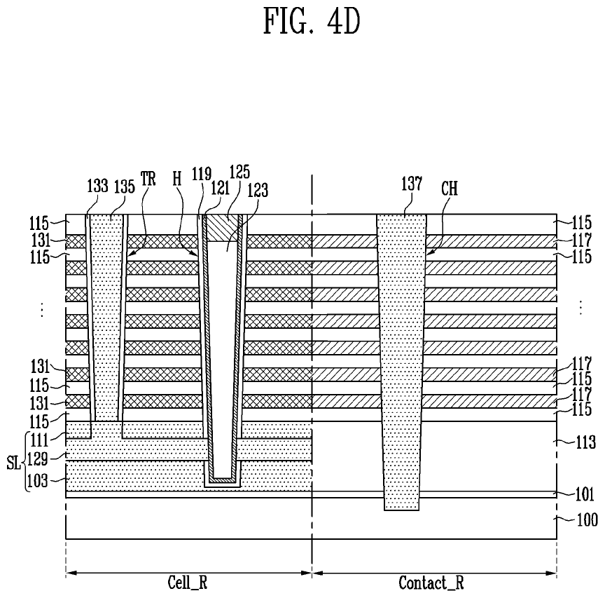

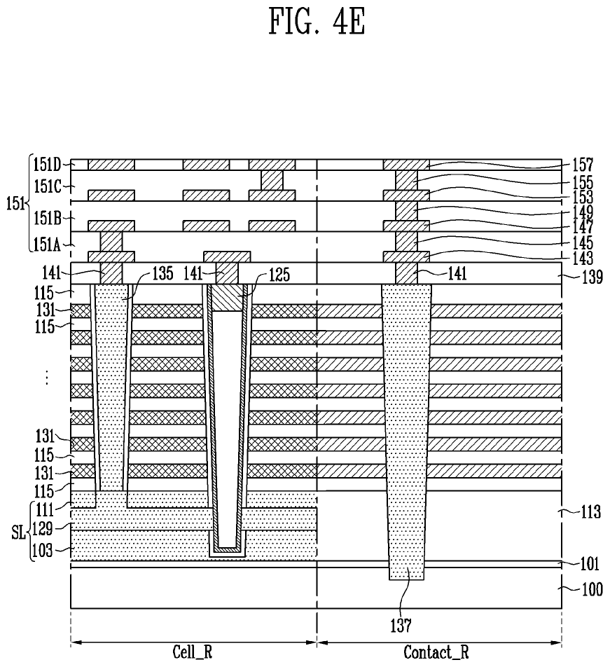

FIGS. 4A to 4E, 5, 6, and 7A to 7D are cross-sectional views illustrating a method of manufacturing a semiconductor memory device according to the present disclosure.

FIGS. 4A to 4E are cross-sectional views illustrating a step of forming a memory cell array, a first wiring array, and first connection structures on a first substrate.

Referring to FIG. 4A, a protective layer 101 is formed on the first substrate 100 defined by a cell region Cell_R and a contact region Contact_R. The protective layer 101 may be formed of a nitride layer or an oxide layer. The first substrate 100 may be a sacrificial substrate. The cell region Cell_R may be a region in which memory cells are formed, and the contact region Contact_R may be defined as a region in which contact plugs are formed.

Thereafter, a first source layer 103, source sacrificial layers 105, 107, and 109, and a second source layer 111 are formed on the protective layer 101. The first source layer 103 and the second source layer 111 may include a polysilicon layer. The first source layer 103 and the second source layer 111 may include an N-type or P-type impurity. The source sacrificial layers 105, 107, and 109 may include first source sacrificial layers 105, second source sacrificial layers 107, and a third source sacrificial layer 109. As another example, differently from that shown, the source sacrificial layer may be configured of a single layer. Hereinafter, the source sacrificial layer is described as including the first to third source sacrificial layers 105, 107, and 109, but a structure of the source sacrificial layer might not be limited thereto. For example, the first source sacrificial layer 105 may include an oxide or a dielectric constant (high-k) material. For example, the high dielectric constant material may include Al₂O₃. For example, the second source sacrificial layer 107 may include polysilicon. For example, the third source sacrificial layer 109 may include an oxide or a dielectric constant (high-k) material.

Thereafter, after removing the source sacrificial layers 105, 107, and 109 formed in the contact region Contact_R, a buffer insulating layer 113 may be formed in a region from which the source sacrificial layers 105, 107, and 109 are removed. The buffer insulating layer 113 may be formed of an oxide layer.

Thereafter, a stack ST is formed on the source sacrificial layers 105, 107, and 109 of the cell region Cell_R and the buffer insulating layer 113 of the contact region Contact_R. The stack ST may include first material layers 115 and second material layers 117 that are alternately stacked. The second material layers 117 may be for forming a gate electrode of a memory cell, a select transistor, and the like, and the first material layers 115 may be for insulating stacked gate electrodes from each other. The second material layers 117 are formed of a material having a high etch selectivity with respect to the first material layers 115. For example, the first material layers 115 may be insulating layers including an oxide or the like, and the second material layers 117 may be sacrificial layers including nitride or the like. As another example, the first material layers 115 may be insulating layers including an oxide, and the second material layers 117 may be conductive layers including polysilicon, tungsten, or the like.

Referring to FIG. 4B, a hole H extending into the first source layer 103 by passing through the stack ST of the cell region Cell_R is formed. For example, the hole H may extend into the first source layer 103 by passing through the stack ST, the second source layer 111, and the source sacrificial layers 105, 107, and 109 in the cell region Cell_R.

Thereafter, a memory layer 119 is formed on a sidewall and a bottom surface of the hole H. The memory layer 119 may include at least one of a tunneling layer, a data storage layer, and a blocking layer. The data storage layer may include a floating gate, a charge trap material, polysilicon, nitride, a variable resistance material, a nano structure, or a combination thereof. Thereafter, a channel layer 121 is formed along a surface of the memory layer 119. The channel layer 121 may include a semiconductor material such as silicon or germanium. Thereafter, a backgate sacrificial layer 123 may be formed so that a central region of the hole H is completely buried. The backgate sacrificial layer 123 may be formed of an oxide layer. Thereafter, a recessed region is formed by etching a portion of an upper end of the backgate sacrificial layer 123, and a capping layer 125 is formed in the recess region. The capping layer 125 may include a conductive material and may be directly connected to the channel layer 121. A lower surface height of the capping layer 125 may be equal to or lower than an upper surface of the second material layer 117 disposed at the uppermost portion of the plurality of second material layers 117. The memory layer 119, the channel layer 121, the backgate sacrificial layer 123, and the capping layer 125 may be defined as a preliminary channel plug.

Referring to FIG. 4C, a source sacrificial layer is exposed by forming a trench TR passing through the stack ST and the second source layer 111 of the cell region Cell_R, and a sacrificial spacer 127 is formed on a sidewall of the trench TR. Thereafter, the source sacrificial layer exposed by the trench TR is removed. A portion of the memory layer 119 is exposed by a space from which the source sacrificial layer is removed. Thereafter, a portion of the channel layer 121a is exposed by etching a portion of the exposed memory layer 119.

Thereafter, a third source layer 129 is formed in a space from which the source sacrificial layer is removed. The third source layer 129 may be formed of polysilicon doped with a dopant. Accordingly, the source lines SL 103, 111, and 129 connected to a partial sidewall of the channel layer 121 are formed.

Referring to FIG. 4D, a sidewall of the second material layers 117 of FIG. 4C is exposed by removing the sacrificial spacer 127 of FIG. 4C. Thereafter, a recess region is formed by removing the second material layers 117 of FIG. 4C of the cell region Cell_R exposed by the trench TR, and gate patterns 131 are formed by filling the recess region with a conductive material. At this time, the second material layers 117 of the contact region Contact_R may remain without being removed. Thereafter, after forming a spacer layer 133 on a sidewall of the trench TR, a wiring 135 connected to the source lines SL 103, 111, and 129 is formed by filling the trench TR with a conductive material. A plurality of gate patterns 131 and a plurality of first material layers 115 may be defined as a gate stack. The first material layers 115 may also be referred to as interlayer insulating layers.

Thereafter, a contact hole CH passing through the first material layers 115, the second material layers 117, the buffer insulating layer 113, and the protective layer 101 is formed in the contact region Contact_R. The contact hole CH may extend into the first substrate 100.

Thereafter, a contact plug 137 is formed in the contact hole CH. The contact plug may include a metal material such as tungsten.

Referring to FIG. 4E, an insulating layer 139 is formed on the cell region Cell_R and the contact region Contact_R, and contacts 141 respectively connected to the wiring 135, the capping layer 125, and the contact plug 137 by passing through the insulating layer 139 are formed.

A first wiring array 143 may be formed on the insulating layer 139 of the cell region Cell_R. The first wiring array 143 may include a bit line and a source line wiring connected to the contacts 141. A second wiring array 143 may be formed on the insulating layer 139 of the contact region Contact_R, and the second wiring array 143 may be electrically connected to the contact plug 137. Thereafter, a first insulating structure 151 covering the first and second wiring arrays 143 may be formed. The first insulating structure 151 may include two or more insulating layers 151A to 151D. First connection structures 147, 153, and 157 may be buried in the first insulating structure 151, and the first connection structures 147, 153, and 157 may be electrically connected through the contacts (for example, 145, 149, 155).

The first connection structures 147, 153, and 157 may include a first bonding metal 157 having a surface exposed to an outside of the first insulating structure 151.

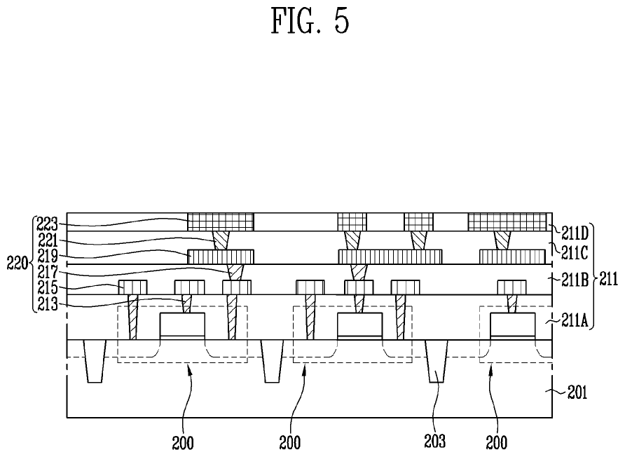

FIG. 5 is a cross-sectional view illustrating a step of forming a complementary metal oxide semiconductor (CMOS) circuit and second connection structures on a second substrate.

Referring to FIG. 5, a plurality of transistors 200 configuring the CMOS circuit on the second substrate 201 may be formed.

The second substrate 201 may be a bulk silicon substrate, a silicon on insulator substrate, a germanium substrate, a germanium on insulator substrate, a silicon-germanium substrate, or an epitaxial layer formed through a selective epitaxial growth method.

Each of the transistors 200 may be formed in an active region of the second substrate 201 partitioned by an isolation layer 203.

After forming the plurality of transistors 200, second connection structures 220 connected to the transistors 200 configuring the CMOS circuit, and second insulating structures 211 covering the second connection structures 220 and the transistors 200 may be formed.

The second insulating structure 211 may include two or more insulating layers 211A to 211D. The second connection structures 220 may be buried in the second insulating structure 211. Each of the second connection structures 220 may include a plurality of conductive patterns 213, 215, 217, 219, 221, and 223. The second insulating structure 211 and the second connection structures 220 are not limited to an example shown in the drawing and may be variously changed.

The conductive patterns 213, 215, 217, 219, 221, and 223 included in each of the second connection structures 220 may include a second bonding metal 223 having a surface exposed to an outside of the second insulating structure 211.

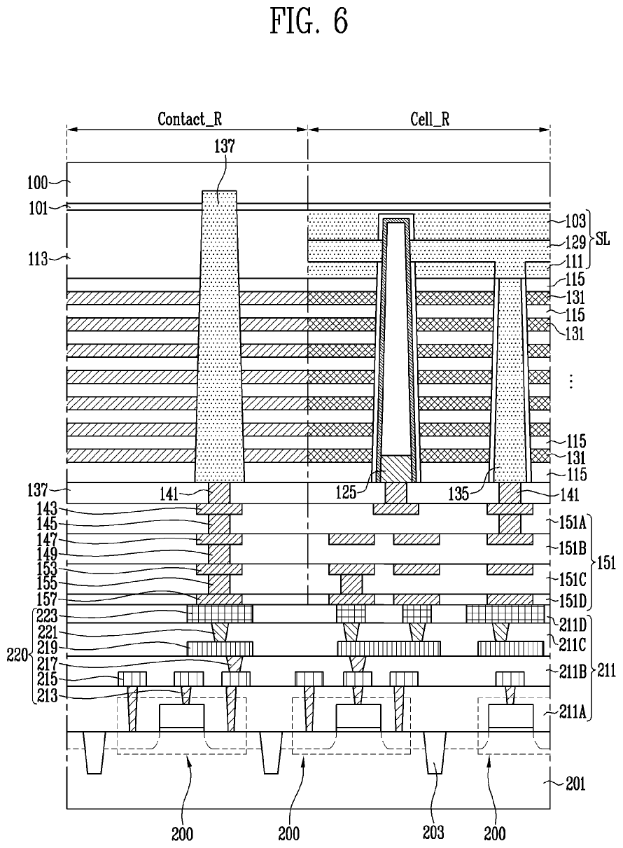

FIG. 6 is a cross-sectional view illustrating a step of bonding the first connection structures and the second connection structures to each other.

Referring to FIG. 6, the first substrate 100 and the second substrate 201 are aligned so that a first bonding metal 157 on the first substrate 100 and a second bonding metal 223 on the second substrate 201 may be in contact with each other. The first bonding metal 157 and the second bonding metal 223 may include various metals, and may include, for example, copper.

Thereafter, the first bonding metal 157 and the second bonding metal 223 are bonded to each other. To this end, after heat is applied to the first bonding metal 157 and the second bonding metal 223, the first bonding metal 157 and the second bonding metal 223 may be hardened. The present disclosure is not limited thereto, and various processes for connecting the first bonding metal 157 and the second bonding metal 223 may be introduced.

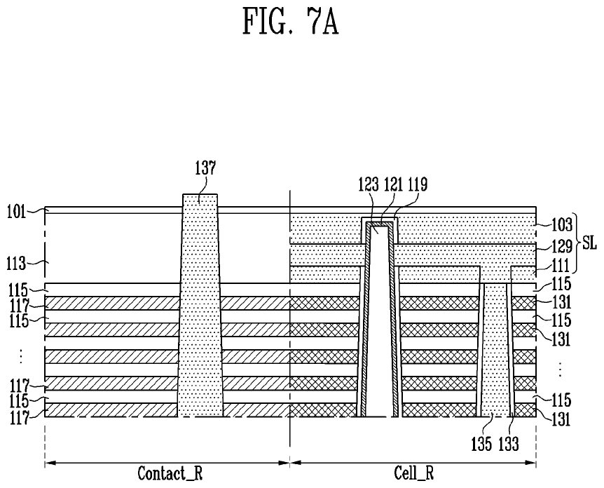

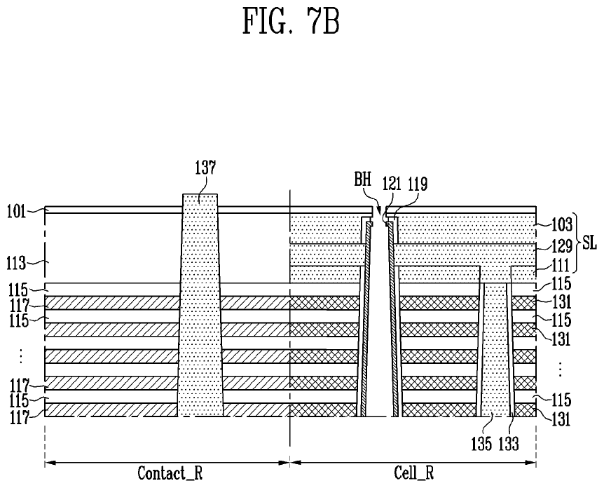

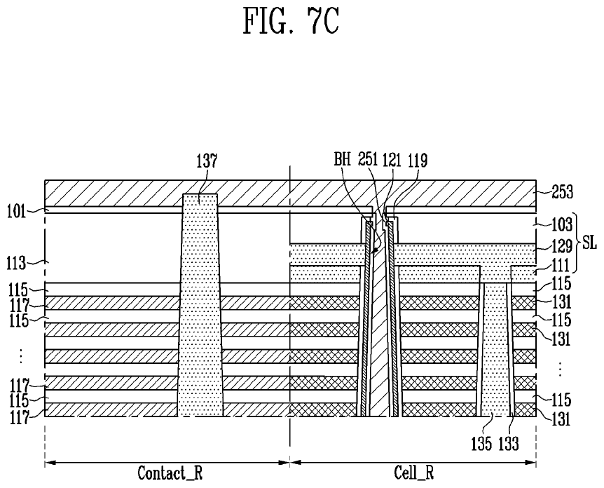

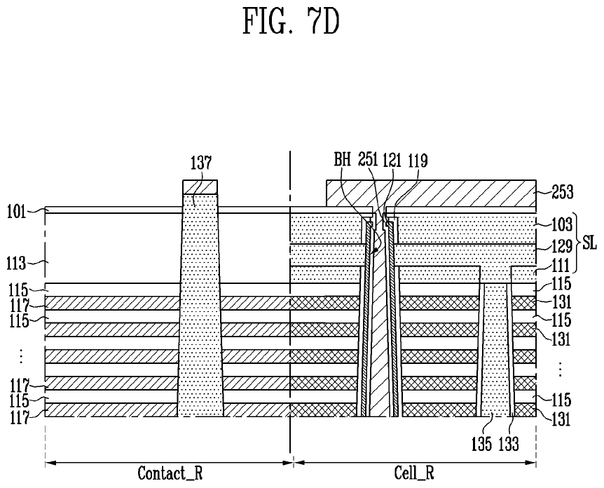

FIGS. 7A to 7D are cross-sectional views illustrating a step of forming a backgate surrounded by the channel layer 121 of the cell region Cell_R and a backgate line structure connected to the backgate.

Referring to FIG. 7A, the first substrate 100 shown in FIG. 6 is removed. Accordingly, the protective layer 101 may be exposed, and the contact plug 137 formed in the contact region Contact_R may protrude by passing through the protective layer 101.

Referring to FIG. 7B, a backgate hole BH exposing an upper surface of the memory layer 119 by passing through the protective layer 101 and the first source layer 103 is formed by performing an etching process using a mask. The backgate hole BH may be formed to overlap the preliminary channel plug including the memory layer 119 and the channel layer 121.

Thereafter, the backgate sacrificial layer 123 of FIG. 4D is exposed by sequentially etching the memory layer 119 and the channel layer 121 exposed through the backgate hole BH, and the exposed backgate sacrificial layer is removed.

Referring to FIG. 7C, a backgate insulating layer 251 covering the backgate hole BH including an exposed surface of the first source layer 103, an exposed surface of the memory layer 119, and a surface of the channel layer 121 exposed by removing the backgate sacrificial layer is formed. The backgate insulating layer 251 may be formed of an oxide layer.

Thereafter, a backgate structure 253 is formed by forming a conductive material inside the backgate hole BH and on the entire structure. The backgate structure layer 253 may be formed of a doped polysilicon layer or a metal material layer. The memory layer 119, the channel layer 121, the backgate insulating layer 251, and the backgate structure layer 253 may be defined as a channel plug. The backgate insulating layer 251 electrically and physically separates the backgate structure layer 253 from the channel layer 121. The backgate insulating layer 251 electrically and physically separates the backgate structure layer 253 from the memory layer 119. In addition, the backgate insulating layer 251 electrically and physically separates the backgate structure layer 253 from the first source layer 103.

Referring to FIG. 7D, a patterning process for electrically and physically separating the backgate structure layer 253 formed on the cell region Cell_R and the backgate structure layer 253 formed on the contact region Contact_R from each other is performed. The backgate structure layer 253 formed on the cell region Cell_R is electrically isolated from the contact plug 137 of the contact region Contact_R by the patterning process. The backgate structure layer 253 may include the backgate formed inside the channel plug and the backgate line connected thereto.

According to the embodiment of the present disclosure described above, the backgate structure layer 253 formed inside the channel plug is formed by passing through the source line SL, and is electrically and physically separated from the contact plug 137 formed in the contact region Contact_R by the patterning process. In addition, a process is simplified by forming the backgate formed inside the channel plug and the line for connecting the same with the same material.

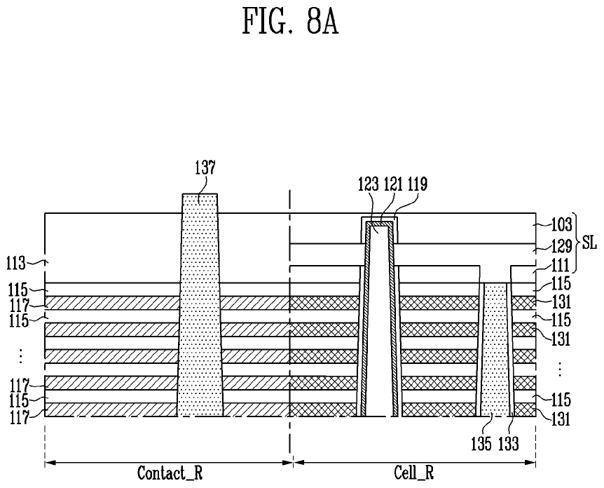

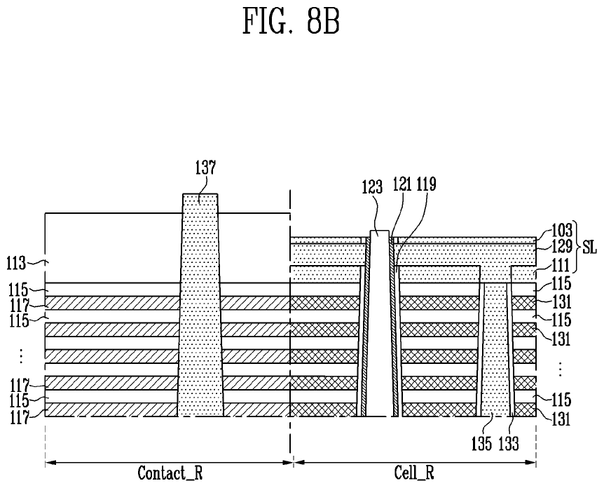

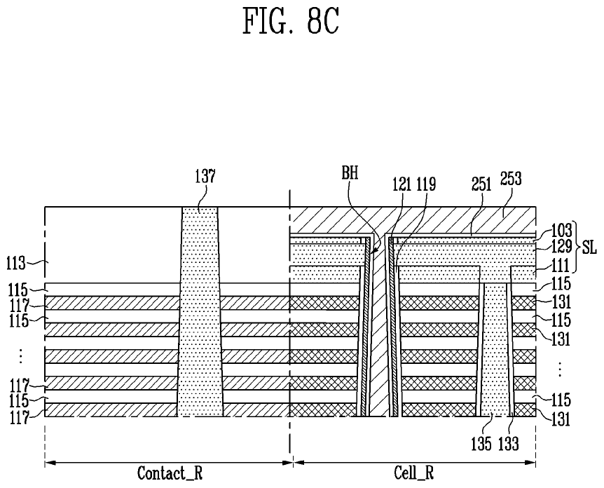

FIGS. 8A to 8C are cross-sectional views illustrating another method of manufacturing a semiconductor memory device according to the present disclosure.

FIGS. 8A to 8C are diagrams illustrating a process of forming the backgate and the backgate line connected to the backgate described with reference to FIGS. 7A to 7D.

Referring to FIG. 8A, the first substrate 100 and the first protective layer 101 shown in FIG. 6 are sequentially removed. Accordingly, the buffer insulating layer 113 of the contact region Contact_R and the first source layer 103 of the cell region Cell_R are exposed. The contact plug 137 formed in the contact region Contact_R may protrude by passing through the buffer insulating layer 113.

Referring to FIG. 8B, the first source layer 103 is etched by a certain thickness by performing an etching process. Accordingly, a portion of the preliminary channel plug may protrude compared to the first source layer 103. For example, the memory layer 119, the channel layer 121, and the backgate sacrificial layer 123 may be formed to protrude compared to the first source layer 103.

In addition, an upper end surface of the buffer insulating layer 113 is as high as an upper end surface of the first source layer 103 by a thickness of the etched first source layer 103. That is, a step difference between the buffer insulating layer 113 and the first source layer 103 occurs.

Thereafter, the backgate sacrificial layer 123 may be exposed by sequentially etching the protruding memory layer 119 and the channel layer 121.

Referring to FIG. 8C, the backgate hole BH is formed by removing the exposed backgate sacrificial layer 123 of FIG. 813, and the backgate insulating layer 251 is formed along a sidewall of the backgate hole BH and an upper surface of the first source layer 103. Thereafter, the backgate structure layer 253 is formed by forming a conductive material inside the backgate hole BH and on the entire structure. The backgate structure layer 253 may be formed of a doped polysilicon layer or a metal material layer. The memory layer 119, the channel layer 121, the backgate insulating layer 251, and the backgate structure layer 253 may be defined as the channel plug. The backgate insulating layer 251 electrically and physically separates the backgate structure layer 253 from the channel layer 121. In addition, the backgate insulating layer 251 electrically and physically separates the backgate structure layer 253 from the first source layer 103.

Thereafter, the backgate structure layer 253 formed in the contact region Contact_R is removed by performing a planarization process to expose the buffer insulating layer 113 of the contact region Contact_R. Accordingly, the backgate structure layer 253 is electrically and physically separated from the contact plug 137 of the contact region Contact_R.

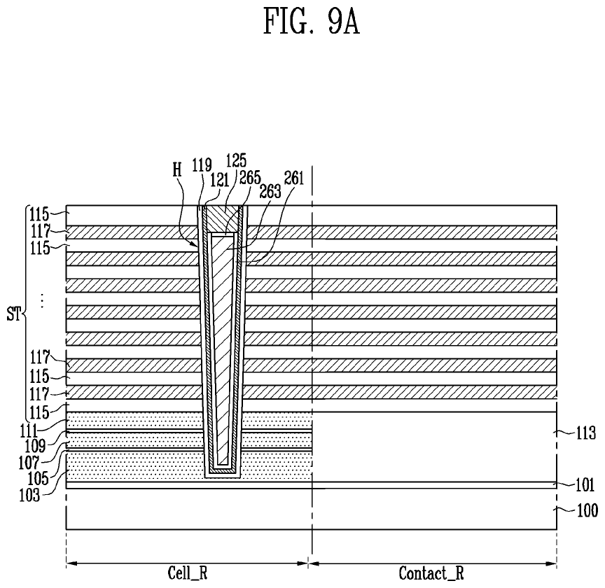

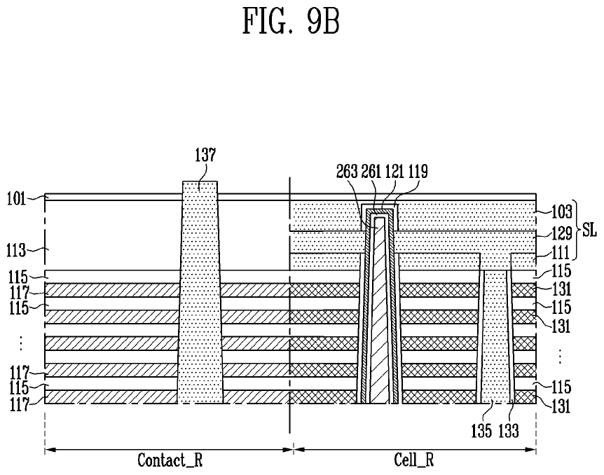

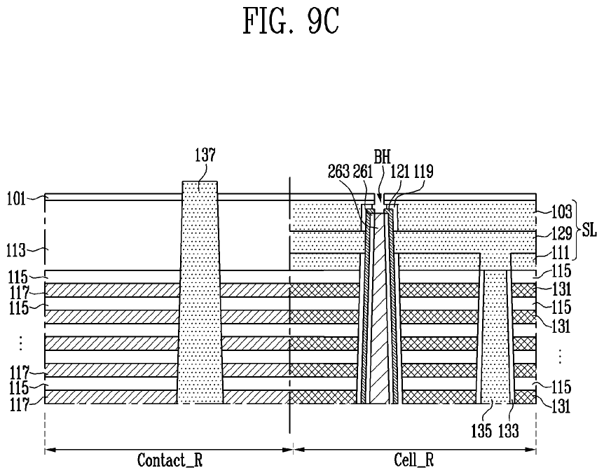

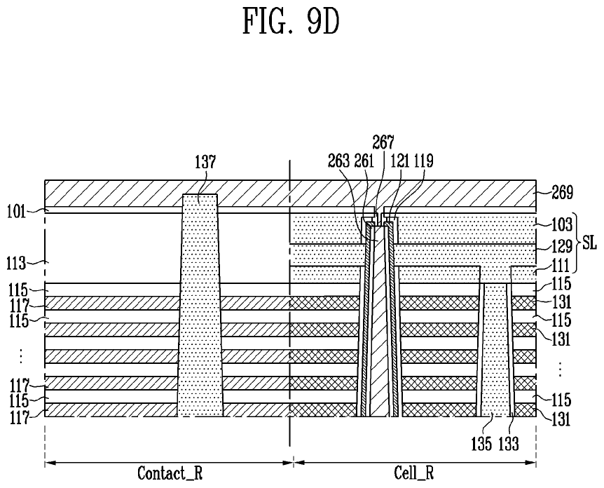

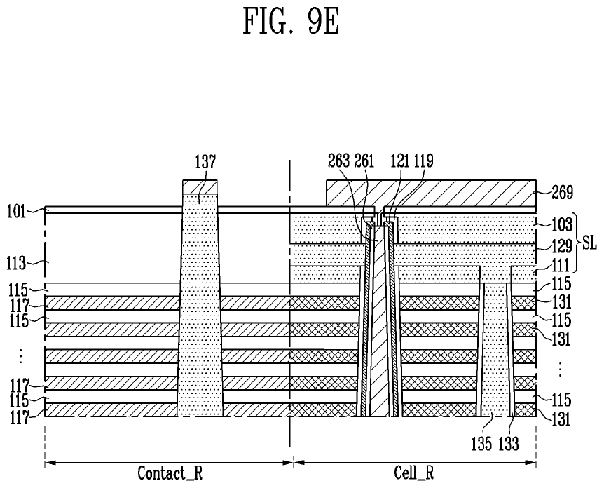

FIGS. 9A to 9E are cross-sectional views illustrating another method of manufacturing a semiconductor memory device according to the present disclosure.

FIGS. 9A to 9E are diagrams illustrating a manufacturing method of forming the backgate line connected to the backgate after a wafer bonding process after forming the backgate in the channel plug.

In the present embodiment, before performing the wafer bonding process, the channel plug may be formed on the first substrate, and the backgate may be formed in the channel plug.

For example, as shown in FIG. 4A, the protective layer 101 is formed on the first substrate 100 defined as the cell region Cell_R and the contact region Contact_R, and the first source layer 103, the source sacrificial layers 105, 107, and 109, and the second source layer 111 are formed on the protective layer 101. Thereafter, after removing the source sacrificial layers 105, 107, and 109 formed in the contact region Contact_R, the buffer insulating layer 113 may be formed in a region from which the source sacrificial layers 105, 107, and 109 are removed.

Thereafter, the stack ST is formed on the source sacrificial layers 105, 107, and 109 of the cell region Cell_R and the buffer insulating layer 113 of the contact region Contact_R.

Referring to FIG. 9A, a hole H extending into the first source layer 103 by passing through the stack ST of the cell region Cell_R is formed. For example, the hole H may extend into the first source layer 103 by passing through the stack ST, the second source layer 111, and the source sacrificial layers 105, 107, and 109 in the cell region Cell_R.

Thereafter, the memory layer 119 is formed on a sidewall and a bottom surface of the hole H. The memory layer 119 may include at least one of a tunneling layer, a data storage layer, or a blocking layer. The data storage layer may include a floating gate, a charge trap material, polysilicon, nitride, a variable resistance material, a nanostructure, or a combination thereof. Thereafter, the channel layer 121 is formed along a surface of the memory layer 119. The channel layer 121 may include a semiconductor material such as silicon or germanium. Thereafter, a first backgate insulating layer 261 is formed along a surface of the channel layer 121. The first backgate insulating layer 261 may include an oxide. Thereafter, a backgate 263 may be formed so that a central region of the hole H is completely buried. The backgate 263 may be formed of a conductive material such as a polysilicon layer or a tungsten layer. Thereafter, a recess region is formed by etching the first backgate insulating layer 261 and a portion of an upper end portion of the backgate 263, and a second backgate insulating layer 265 is formed to cover the upper end portion of the backgate 263. Thereafter, a capping layer 125 filling the recess region is formed on the second backgate insulating layer 265. The capping layer 125 may include a conductive material and may be directly connected to the channel layer 121.

Thereafter, the process of forming the source line SL, the process of forming the contact plug 137, and the process of forming the first connection structures described above with reference to FIGS. 4C to 4E are performed, and the process of forming the CMOS circuit and the second connection structures on the second substrate described with reference to FIG. 5 and the wafer bonding process of bonding the first connection structures and the second connection structures described with reference to FIG. 6 may be performed. A description thereof is omitted.

FIGS. 9B to 9E are cross-sectional views illustrating a step of forming a backgate line structure connected to the backgate 263 formed in the channel plug of the cell region Cell_R after the wafer bonding process step of FIG. 6 is completed.

Referring to FIG. 913, the first substrate 100 shown in FIG. 9A is removed. Accordingly, the protective layer 101 may be exposed, and the contact plug 137 formed in the contact region Contact_R may protrude by passing through the protective layer 101.

Referring to FIG. 9C, the backgate hole BH exposing the upper surface of the memory layer 119 by passing through the protective layer 101 and the first source layer 103 is formed by performing an etching process using a mask. The backgate hole BH may be formed to overlap the channel plug including the memory layer 119, the channel layer 121, the first backgate insulating layer 261, and the backgate 263.

Thereafter, the backgate 263 is exposed by sequentially etching the memory layer 119, the channel layer 121, and the first backgate insulating layer 261 exposed through the backgate hole BH.

Referring to FIG. 9D, a third backgate insulating layer 267 is formed to cover a sidewall of the first source layer 103, a sidewall of the memory layer 119, and a sidewall of the channel layer 121 exposed through the sidewall of the backgate hole BH of FIG. 9C. The third backgate insulating layer 267 may be formed of an oxide layer.

Thereafter, a conductive layer for backgate line 269 is formed on the entire structure including an inside of the backgate hole BH of FIG. 9C. The conductive layer for backgate line 269 may be formed of a doped polysilicon layer or a metal material layer. The third backgate insulating layer 267 electrically and physically separates the conductive layer for backgate line 269 from the first source layer 103. In addition, the third backgate insulating layer 267 electrically and physically separates the conductive layer for backgate line 269 from the channel layer 121 and the memory layer 119.

Referring to FIG. 9E, a patterning process for electrically and physically separating the conductive layer for backgate line 269 formed on the cell region Cell_R from the conductive layer for backgate line 269 formed on the contact region Contact_R is performed. The conductive layer for backgate line 269 formed on the cell region Cell_R is electrically isolated from the contact plug 137 of the contact region Contact_R by the patterning process.

According to the above-described embodiment, after the channel plug including the backgate is formed, the wafer bonding process may be performed, and the backgate line connected to the backgate through a lower end portion of the channel plug may be formed.

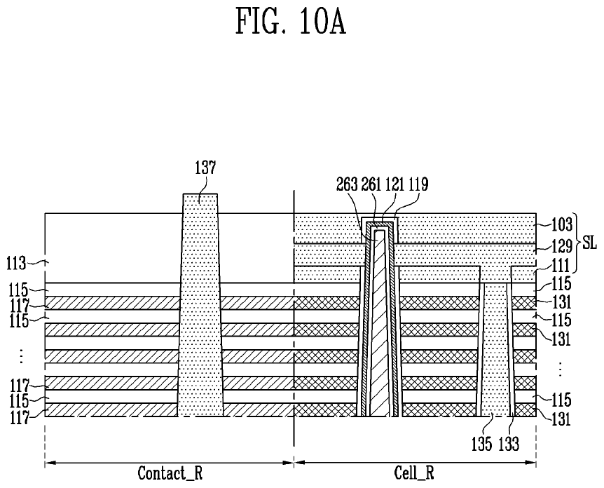

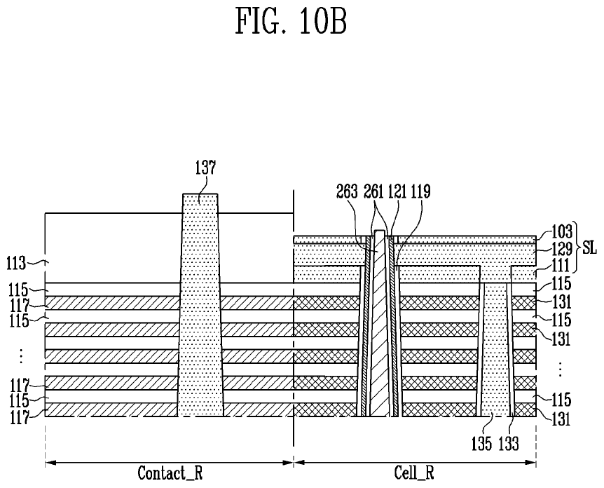

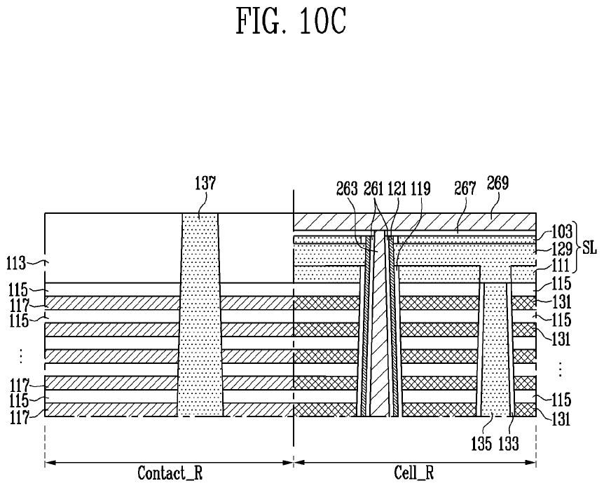

FIGS. 10A to 10C are cross-sectional views illustrating another method of manufacturing a semiconductor memory device according to the present disclosure.

FIGS. 10A to 10C are diagrams illustrating a process of forming the backgate and the backgate line connected to the backgate described with reference to FIGS. 9B to 9E.

Referring to FIG. 10A, the first substrate 100 and the protective layer 101 shown in FIG. 9A described above are sequentially removed. Accordingly, the buffer insulating layer 113 of the contact region Contact_R and the first source layer 103 of the cell region Cell_R are exposed.

The contact plug 137 formed in the contact region Contact_R may protrude by passing through the buffer insulating layer 113.

Referring to FIG. 10B, the first source layer 103 is etched by a certain thickness by performing an etching process. Accordingly, a portion of the channel plug may protrude compared to the first source layer 103. For example, the memory layer 119, the channel layer 121, the first backgate insulating layer 261, and the backgate 263 may be formed to protrude compared to the first source layer 103.

In addition, the upper end surface of the buffer insulating layer 113 is as high as the upper end surface of the first source layer 103 by a thickness of the etched first source layer 103. That is, the step difference between the buffer insulating layer 113 and the first source layer 103 occurs.

Thereafter, the backgate 263 may be exposed by sequentially etching the protruding memory layer 119, the channel layer 121, and the first backgate insulating layer 261.

Referring to FIG. 10C, the third backgate insulating layer 267 is formed to cover the sidewall of the first source layer 103, the sidewall of the exposed memory layer 119, and the sidewall of the exposed channel layer 121. The third backgate insulating layer 267 may be formed of an oxide layer. The third backgate insulating layer 267 may be formed to expose a partial surface of the backgate 263. The third backgate insulating layer 267 may be in contact with the first backgate insulating layer 261.

Thereafter, the conductive layer for backgate line 269 is formed on the third backgate insulating layer 267. The conductive layer for backgate line 269 may be formed of a doped polysilicon layer or a metal material layer. The conductive layer for backgate line 269 is in contact with the backgate 263. The third backgate insulating layer 267 electrically and physically separates the conductive layer 269 for backgate line from the first source layer 103. In addition, the third backgate insulating layer 267 electrically and physically separates the conductive layer for backgate line 269 from the channel layer 121 and the memory layer 119.

Thereafter, the conductive layer for backgate line 269 formed in the contact region Contact_R is removed by performing a planarization process to expose the buffer insulating layer 113 of the contact region Contact_R. Accordingly, the conductive layer for backgate line 269 is electrically and physically separated from the contact plug 137 of the contact region Contact_R.

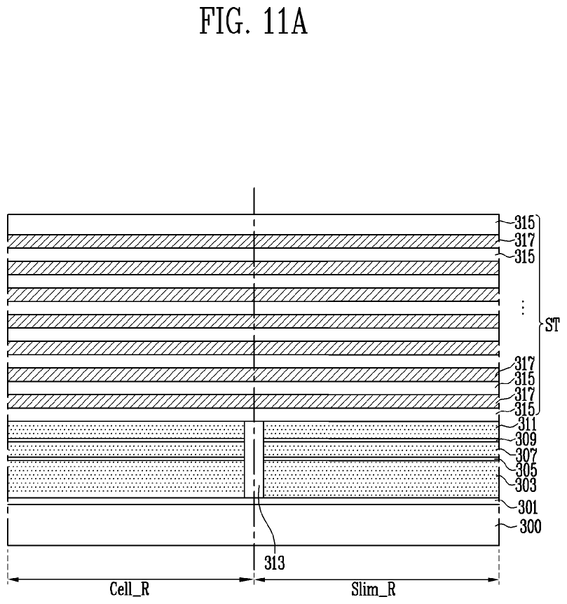

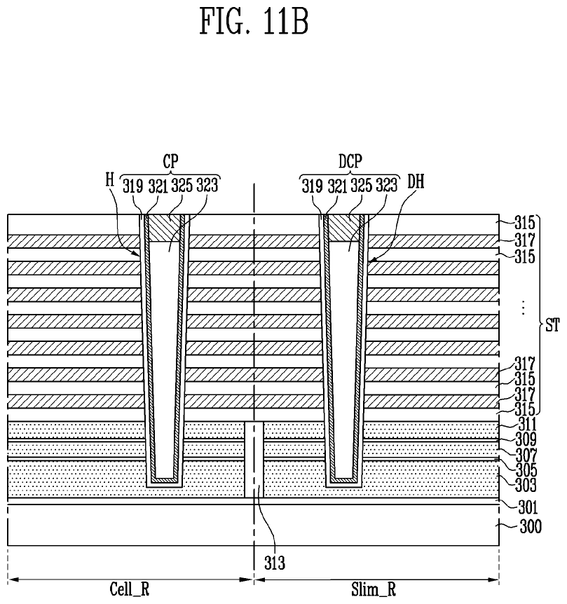

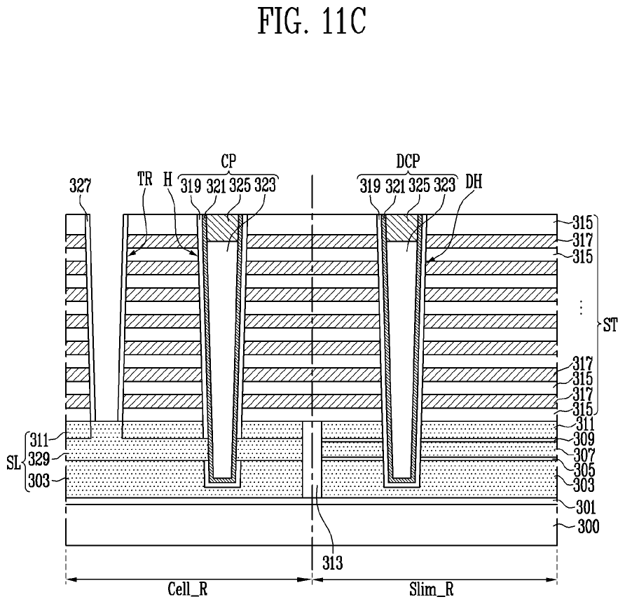

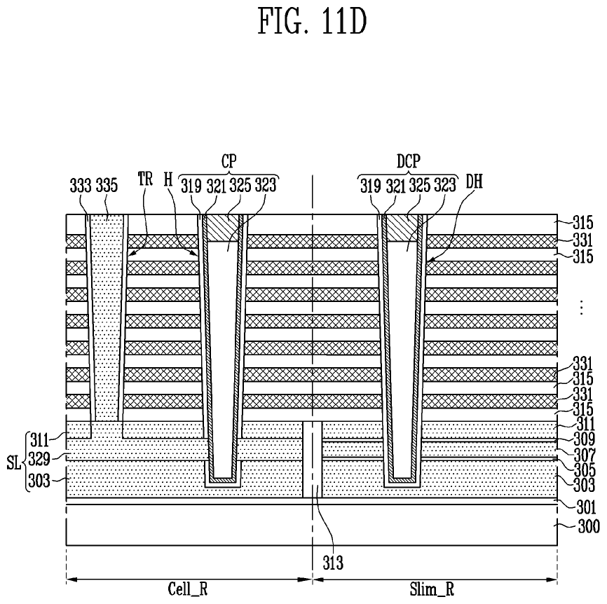

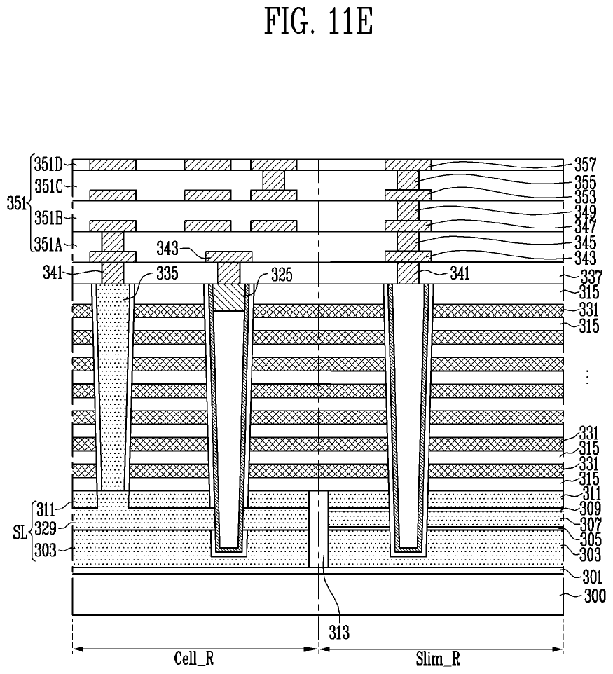

FIGS. 11A to 11E, 12, and 13A to 13C are cross-sectional views illustrating another method of manufacturing a semiconductor memory device according to the present disclosure.

FIGS. 11A to 11E are cross-sectional views illustrating a step of forming a memory cell array, a first wiring array, and first connection structures on a first substrate.

Referring to FIG. 11A, a protective layer 301 is formed on a first substrate 300 defined as a cell region Cell_R and a slimming region Slim_R. The protective layer 301 may be formed of a nitride layer or an oxide layer. The first substrate 300 may be a sacrificial substrate. The cell region Cell_R may be a region in which memory cells are formed, and the slimming region Slim_R may be a region disposed adjacent to the cell region Cell_R and may be defined as a region in which a gate electrode connected to the memory cells is extended and disposed.

Thereafter, a first source layer 303, source sacrificial layers 305, 307, and 309, and a second source layer 311 are formed on the protective layer 301. The first source layer 303 and the second source layer 311 may include a polysilicon layer. The first source layer 303 and the second source layer 311 may include an N-type or P-type impurity. The source sacrificial layers 305, 307, and 309 may include a first source sacrificial layer 305, a second source sacrificial layer 307, and a third source sacrificial layer 309. As another example, differently from that shown, the source sacrificial layer may be configured of a single layer. Hereinafter, the source sacrificial layer is described as including the first to third source sacrificial layers 305, 307, and 309, but a structure of the source sacrificial layer might not be limited thereto. For example, the first source sacrificial layer 305 may include an oxide or a high dielectric constant (high-k) material. For example, the high dielectric constant material may include Al₂O₃. For example, the second source sacrificial layer 307 may include polysilicon. For example, the third source sacrificial layer 309 may include an oxide or a high dielectric constant (high-k) material.

Thereafter, an isolation structure 313 passing through the first source layer 303, the source sacrificial layers 305, 307, and 309, and the second source layer 311 formed on a boundary between the cell region Cell_R and the slimming region Slim_R is formed. The isolation structure 313 separates the first source layer 303 and the source sacrificial layers 305, 307, and 309 of the cell region Cell_R, and the first source layer 303 and the source sacrificial layers 305, 307, and 309 of the slimming region Slim_R from each other. The isolation structure 313 may be formed of an insulating material such as an oxide layer or a nitride layer.

Thereafter, a stack ST is formed on the source sacrificial layers 305, 307, and 309 of the cell region Cell_R and the source sacrificial layers 305, 307, and 309 of the slimming region Slim_R. The stack ST may include first material layers 315 and second material layers 317 that are alternately stacked. The second material layers 317 may be for forming a gate electrode of a memory cell, a select transistor, and the like, and the first material layers 315 may be for insulating stacked gate electrodes from each other. The first material layers 315 may also be referred to as interlayer insulating layers. The second material layers 317 are formed of a material having a high etch selectivity with respect to the first material layers 315. For example, the first material layers 315 may be insulating layers including an oxide or the like, and the second material layers 317 may be sacrificial layers including nitride or the like. As another example, the first material layers 315 may be insulating layers including an oxide or the like, and the second material layers 317 may be conductive layers including polysilicon, tungsten, or the like.

Referring to FIG. 11B, a hole H extending into the first source layer 303 by passing through the stack ST of the cell region Cell_R is formed. For example, the hole H may extend into the first source layer 303 by passing through the stack ST, the second source layer 311, and the source sacrificial layers 305, 307, and 309 in the cell region Cell_R. During a process of forming the hole H, a dummy hole DH extending into the first source layer 303 by passing through the stack ST of the slimming region Slim_R may be formed together.

Thereafter, a memory layer 319 is formed on a sidewall and a bottom surface of the hole H and the dummy hole DH. The memory layer 319 may include at least one of a tunneling layer, a data storage layer, or a blocking layer. The data storage layer may include a floating gate, a charge trap material, polysilicon, nitride, a variable resistance material, a nano structure, or a combination thereof. Thereafter, a channel layer 321 is formed along a surface of the memory layer 319. The channel layer 321 may include a semiconductor material such as silicon or germanium. Thereafter, a backgate sacrificial layer 323 may be formed to completely fill the central region of the hole H and the dummy hole DH. The backgate sacrificial layer 323 may be formed of an oxide layer. Thereafter, a recess region is formed by etching a portion of an upper end portion of the backgate sacrificial layer 323, and a capping layer 325 is formed in the recess region. The capping layer 325 may include a conductive material and may be directly connected to the channel layer 321. A lower surface height of the capping layer 325 may be equal to or lower than that of an upper surface of the second material layer 317 disposed at the uppermost portion of the plurality of second material layers 317. The memory layer 319, the channel layer 321, the backgate sacrificial layer 323, and the capping layer 325 formed in the hole H of the cell region Cell_R may be defined as a preliminary channel plug CP, the memory layer 319, the channel layer 321, the backgate sacrificial layer 323, and the capping layer 325 formed in the dummy hole DH of the slimming region Slim_R may be defined as a dummy channel plug DCP. The dummy channel plug DCP may be used as a support for preventing the stack ST from collapsing in a subsequent process.

Referring to FIG. 11C, the source sacrificial layer is exposed by forming a trench TR passing through the stack ST of the cell region Cell_R and the second source layer 311, and a sacrificial spacer 327 is formed on a sidewall of the trench TR. Thereafter, the source sacrificial layer exposed by the trench TR is removed. A sidewall of the preliminary channel plug CP, that is, a portion of the memory layer 319 is exposed by a space from which the source sacrificial layer is removed. Thereafter, a portion of the channel layer 321 is exposed by etching a portion of the exposed memory layer 319.

Thereafter, a third source layer 329 is formed in a space from which the source sacrificial layer is removed. The third source layer 329 may be formed of polysilicon doped with a dopant. Accordingly, the source lines SL 303, 311, and 329 connected to a partial sidewall of the channel layer 321 are formed.

Referring to FIG. 11D, a sidewall of the second material layers 317 of FIG. 11C is exposed by removing the sacrificial spacer 327 of FIG. 11C. Thereafter, a recess region is formed by removing the second material layers 317 of FIG. 11C of the cell region Cell_R and the slimming region Slim_R exposed by the trench TR, and gate patterns 331 are formed by filling the recess region with a conductive material. Thereafter, after forming a spacer layer 333 on the sidewall of the trench TR, and a wiring 335 connected to the source lines SL 303, 311, and 329 is formed by filling the trench TR with a conductive material. A plurality of gate patterns 331 and a plurality of first material layers 315 may be defined as a gate stack.

Referring to FIG. 11E, an insulating layer 337 is formed on the cell region Cell_R and the slimming region Slim_R, and contacts 341 respectively connected to the wiring 335 and the capping layers 325 by passing through the insulating layer 337 are formed.

A first wiring array 343 may be formed on the insulating layer 337 of the cell region Cell_R. The first wiring array 343 may include a bit line and a source line wiring connected to the contacts 341. A second wiring array 343 may be formed on the insulating layer 337 of the slimming region Slim_R, and the second wiring array 343 may be electrically connected to the dummy channel plug DCP of FIG. 11C. Thereafter, a first insulating structure 351 covering the first and second wiring arrays 343 may be formed. The first insulating structure 351 may include two or more insulating layers 351A to 351D. First connection structures 347, 353, and 357 may be buried in the first insulating structure 351, and the first connection structures 347, 353, and 357 may be electrically connected through contacts (for example, 345, 349, and 355).

The first connection structures 347, 353, and 357 may include a first bonding metal 357 having a surface exposed to an outside of the first insulating structure 351.

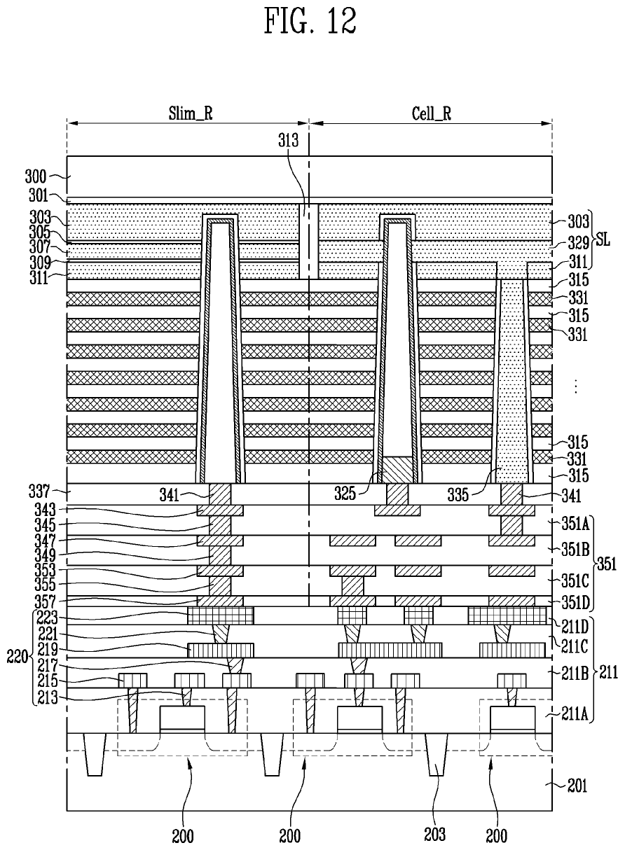

FIG. 12 is a cross-sectional view illustrating a step of bonding the first connection structures and the second connection structures to each other.

Referring to FIG. 12, the first substrate 300 and the second substrate 201 are aligned so that the first bonding metal 357 on the first substrate 300 and the second bonding metal 223 of the second substrate 201 on which the CMOS circuit and the second connection structures described with reference to FIG. 5 are formed. The first bonding metal 357 and the second bonding metal 223 may include various metals, for example, copper.

Thereafter, the first bonding metal 357 and the second bonding metal 223 are bonded to each other. To this end, after heat is applied to the first bonding metal 357 and the second bonding metal 223, the first bonding metal 357 and the second bonding metal 223 may be cured. The present disclosure is not limited thereto, and various processes for connecting the first bonding metal 357 and the second bonding metal 223 may be introduced.

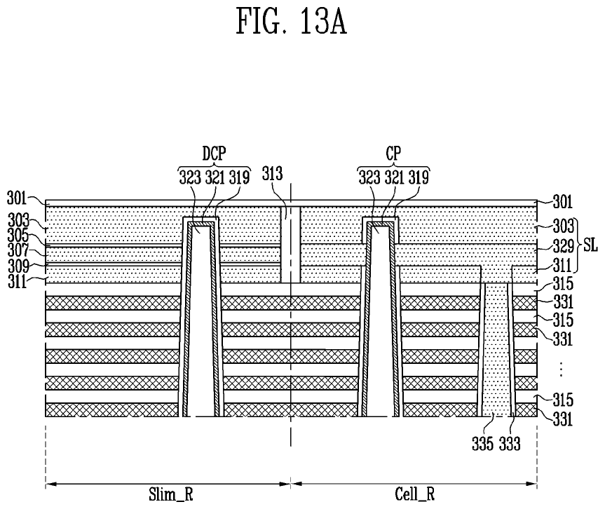

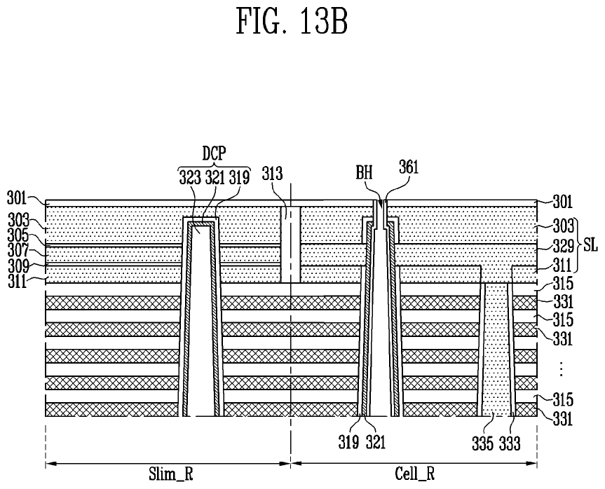

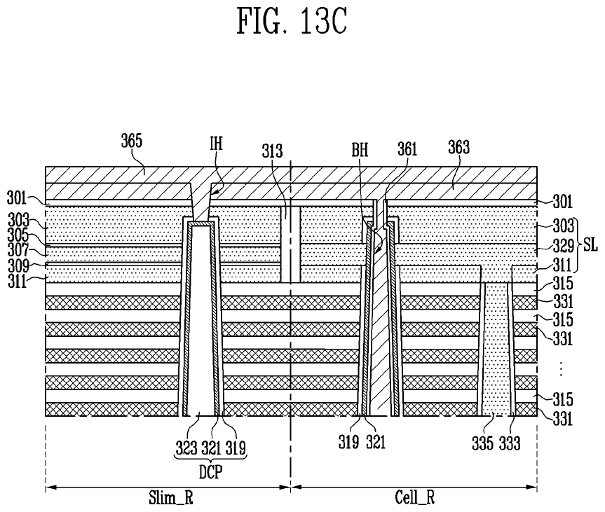

FIGS. 13A to 13C are cross-sectional views illustrating a step of forming the backgate in the preliminary channel plug of the cell region Cell_R and forming the backgate line structure connected to the backgate.

Referring to FIG. 13A, the first substrate 300 shown in FIG. 12 is removed. Accordingly, the protective layer 301 is exposed.

Referring to FIG. 13B, the backgate hole BH exposing an upper surface of the memory layer 319 by passing through the protective layer 301 and the first source layer 303 of the cell region Cell_R is formed by performing an etching process using a mask. The backgate hole BH may be formed to overlap the preliminary channel plug including the memory layer 319, the channel layer 321, and the backgate sacrificial layer.

Thereafter, the backgate sacrificial layer is exposed by sequentially etching the memory layer 319 and the channel layer 321 exposed through the backgate hole BH, and the exposed backgate sacrificial layer is removed.

Referring to FIG. 13C, a backgate insulating layer 361 covering the side of the backgate hole BH including an exposed surface of the first source layer 303, an exposed surface of the memory layer 319, and a surface of the channel layer 321 exposed by removing the backgate sacrificial layer is formed. The backgate insulating layer 361 may be formed of an oxide layer.

Thereafter, a backgate structure layer 363 is formed by forming a conductive material inside the backgate hole BH and on the entire structure. The backgate structure layer 363 may be formed of a doped polysilicon layer or a metal material layer. The memory layer 319, the channel layer 321, the backgate insulating layer 361, and the backgate structure layer 363 may be defined as the channel plug. The backgate insulating layer 361 electrically and physically separates the backgate structure layer 363 from the channel layer 321. The backgate insulating layer 361 electrically and physically separates the backgate structure layer 363 from the memory layer 319. In addition, the backgate insulating layer 361 electrically and physically separates the backgate structure layer 363 from the first source layer 303.

Thereafter, an interconnection hole IH exposing an upper surface of the channel layer 321 of the dummy channel plug DCP by passing through the backgate structure layer 363, the protective layer 301, the first source layer 303, and the memory layer 319 of the slimming region Slim_R is formed by performing an etching process using a mask. The interconnection hole IH may be formed to overlap the dummy channel plug DCP.

Thereafter, a backgate line layer 365 is formed by forming a conductive material inside the interconnection hole IH and on the entire structure. The backgate line layer 365 electrically connects the backgate structure layer 363 and the channel layer 321 of the dummy channel plug DCP. The dummy channel plug DCP may be used as a backgate connection structure.

According to the above-described embodiment of the present disclosure, the backgate structure layer 363 formed inside the channel plug is formed by passing through the source line SL, and the backgate structure layer 363 is electrically connected to the channel layer 321 of the dummy channel plug DCP of the slimming region Slim_R. That is, the backgate structure layer 363 may be electrically connected to the first connection structures through the channel layer 321 of the dummy channel plug DCP.

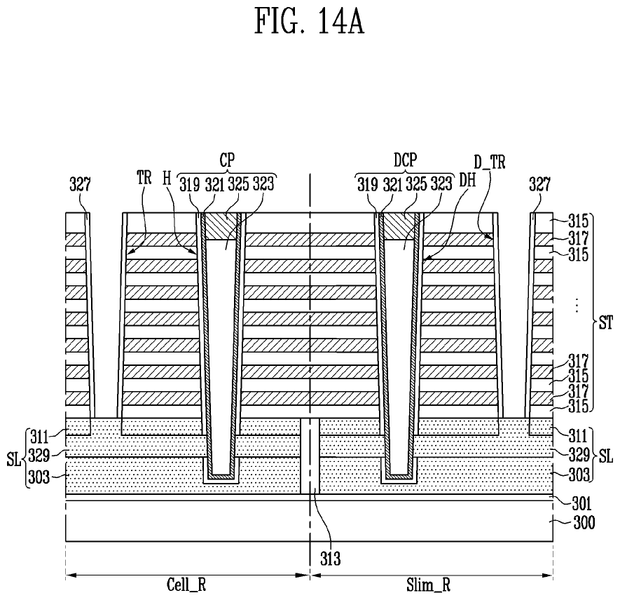

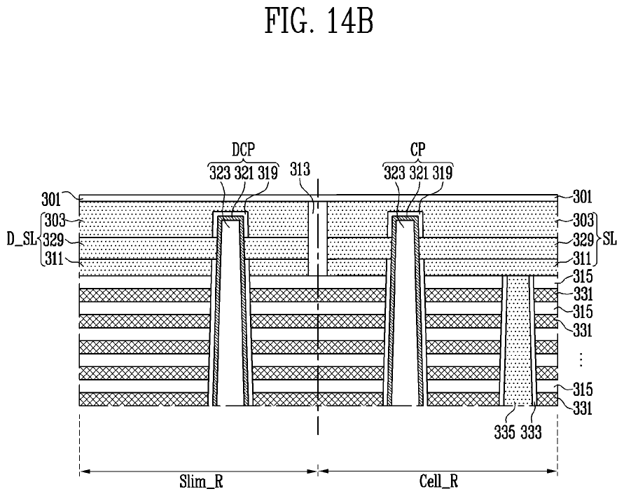

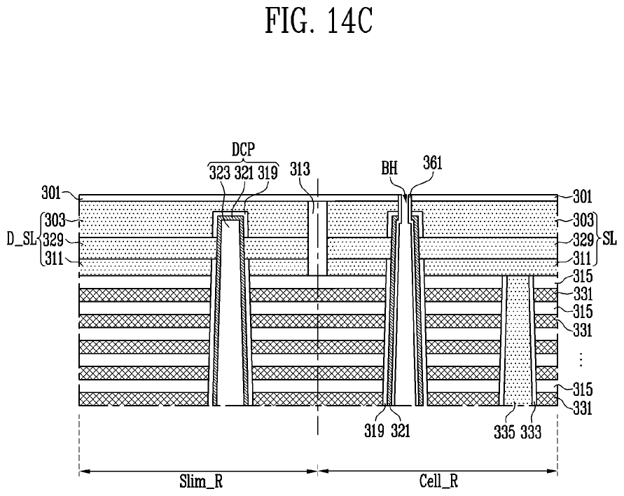

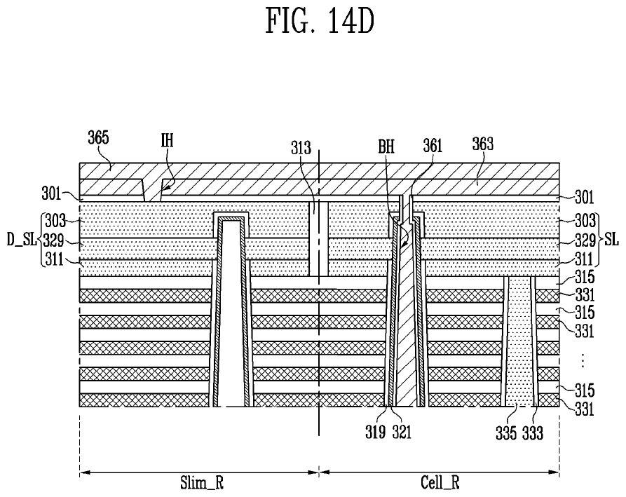

FIGS. 14A to 14D are cross-sectional views illustrating another method of manufacturing a semiconductor memory device according to the present disclosure.

FIGS. 14A to 14D are views illustrating a method of manufacturing the backgate and the backgate line after the wafer bonding process, after forming the source line connected to the preliminary channel plug and the dummy source line connected to the dummy channel plug in the cell region Cell_R and the slimming region Slim_R, respectively.

In the present embodiment, before performing the wafer bonding process, the preliminary channel plug and the dummy channel plug may be formed on the first substrate, and the source line connected to the preliminary channel plug and the dummy source line connected to the dummy channel plug may be formed.

For example, as shown in FIG. 11A, the protective layer 301 is formed on the first substrate 300 defined as the cell region Cell_R and the slimming region Slim_R, and the first source layer 303, the source sacrificial layers 305, 307, and 309, and the second source layer 311 are formed on the protective layer 301. The isolation structure 313 passing through the first source layer 303, the source sacrificial layers 305, 307, and 309, and the second source layer 311 may be formed at a boundary region between the cell region Cell_R and the slimming region Slim_R. The isolation structure 313 separates the first source layer 303 and the source sacrificial layers 305, 307, and 309 of the cell region Cell_R from the first source layer 303 and the source sacrificial layers 305, 307, and 309 of the slimming region Slim_R.

Thereafter, as shown in FIG. 11B, the preliminary channel plug CP extending into the first source layer 303 by passing through the stack ST of the cell region Cell_R and the dummy channel plug DCP extending into the first source layer 303 by passing through the stack ST of the slimming region Slim_R.

Referring to FIG. 14A, the source sacrificial layer is exposed by forming the trench TR passing through the stack ST and the second source layer 311 of the cell region Cell_R, and the sacrificial spacer 327 is formed on the sidewall of the trench TR. In the above-described process, a process of exposing the source sacrificial layer by forming a dummy trench D_TR passing through the stack ST and the second source layer 311 of the slimming region Slim_R and forming the sacrificial spacer 327 on a sidewall of the dummy trench D_TR may be performed together.

Thereafter, the source sacrificial layer exposed by the trench TR and the source sacrificial layer exposed by the dummy trench DTR are removed. A sidewall of the preliminary channel plug CP and a sidewall of the dummy channel plug DCP, that is, a portion of the memory layer 319 is exposed by a space from which the source sacrificial layer is removed. Thereafter, a portion of the channel layer 321 is exposed by etching a portion of the exposed memory layer 319.

Thereafter, the third source layer 329 is formed in the space from which the source sacrificial layer is removed. The third source layer 329 may be formed of polysilicon doped with a dopant. Accordingly, the source lines SL 303, 311, and 329 connected to a partial sidewall of the channel layer 321 are formed in the cell region Cell_R, and dummy source lines D_SL 303, 311, and 329 connected to a partial sidewall of the channel layer 321 are formed in the slimming region Slim_R.

Thereafter, the process of forming the wiring and the first connection structures is performed with reference to FIGS. 11D and 11E described above, and the process of forming the CMOS circuit and the second connection structures on the second substrate described with reference to FIG. 5 and the wafer bonding process of bonding the first connection structures and the second connection structures each other described with reference to FIG. 12 may be performed. A description thereof is omitted.

FIGS. 14B to 14D are cross-sectional views illustrating a step of forming the backgate and the backgate line structure connected to the backgate in the preliminary channel plug of the cell region Cell_R after the wafer bonding process step of FIG. 12 is completed.

Referring to FIG. 14B, the first substrate 300 shown in FIG. 14A is removed. Accordingly, the protective layer 301 is exposed.

Referring to FIG. 14C, the backgate hole BH exposing an upper surface of the memory layer 319 by passing through the protective layer 301 and the first source layer 303 of the cell region Cell_R is formed by performing an etching process using a mask. The backgate hole BH may be formed to overlap the preliminary channel plug including the memory layer 319, the channel layer 321, and the backgate sacrificial layer.

Thereafter, the backgate sacrificial layer is exposed by sequentially etching the memory layer 319 and the channel layer 321 exposed through the backgate hole BH, and the exposed backgate sacrificial layer is removed.

Thereafter, the backgate insulating layer 361 covering the side of the backgate hole BH including an exposed surface of the first source layer 303, an exposed surface of the memory layer 319, and a surface of the channel layer 321 exposed by removing the backgate sacrificial layer is formed. The backgate insulating layer 361 may be formed of an oxide layer.

Referring to FIG. 14D, the backgate structure layer 363 is formed by forming a conductive material inside the backgate hole BH and on the entire structure. The backgate structure layer 363 may be formed of a doped polysilicon layer or a metal material layer. The memory layer 319, the channel layer 321, the backgate insulating layer 361, and the backgate structure layer 363 may be defined as the channel plug. The backgate insulating layer 361 electrically and physically separates the backgate structure layer 363 from the channel layer 321. The backgate insulating layer 361 electrically and physically separates the backgate structure layer 363 from the memory layer 319. In addition, the backgate insulating layer 361 electrically and physically separates the backgate structure layer 363 from the first source layer 303.

Thereafter, an interconnection hole IH exposing the dummy source line D_SL by passing through the backgate structure layer 363 and the protective layer 301 of the slimming region Slim_R is formed by performing an etching process using a mask. Because the interconnection hole IH is formed to expose a portion of the dummy source line D_SL of the slimming region Slim_R, securing a process margin is possible.

Thereafter, the backgate line layer 365 is formed by forming a conductive material inside the interconnection hole IH and on the entire structure. The backgate line layer 365 electrically connects the backgate structure layer 363 and the channel layer 321 of the dummy channel plug DCP.

According to the above-described embodiment of the present disclosure, the backgate structure layer 363 formed inside the channel plug is formed by passing through the source line SL, and the backgate structure layer 363 is electrically connected to the dummy source line D_SL and the channel layer 321 of the slimming region Slim_R. That is, the backgate structure layer 363 may be electrically connected to the first connection structures through the dummy source line DSL of the slimming region Slim_R and the channel layer 321 of the dummy channel plug DCP.

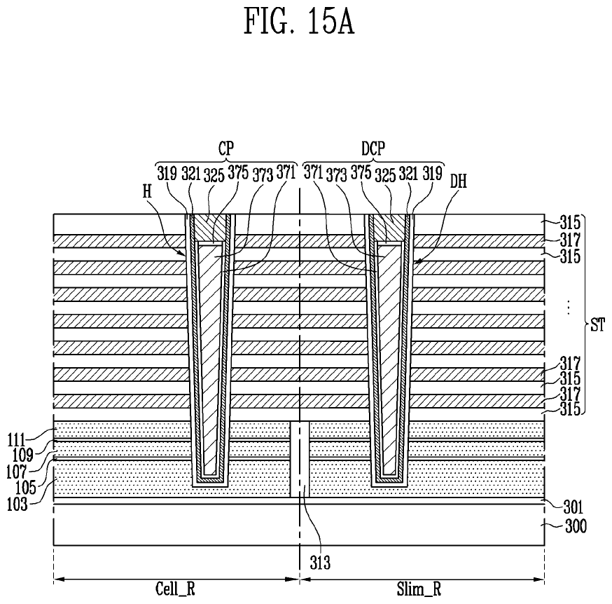

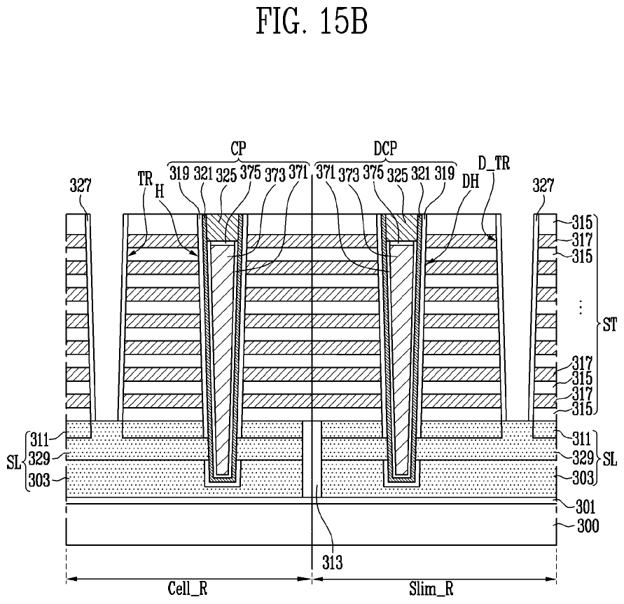

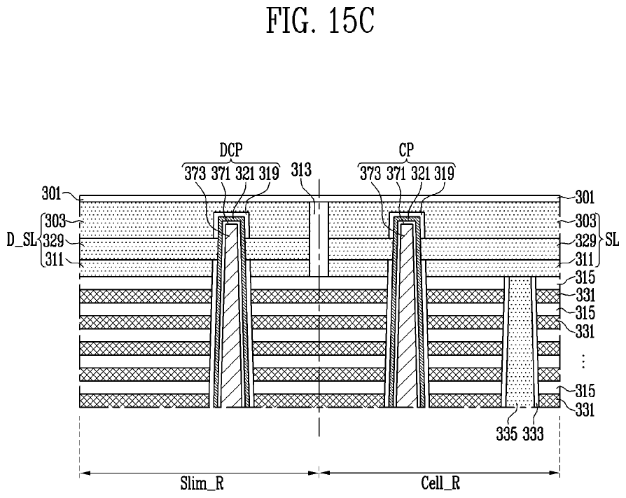

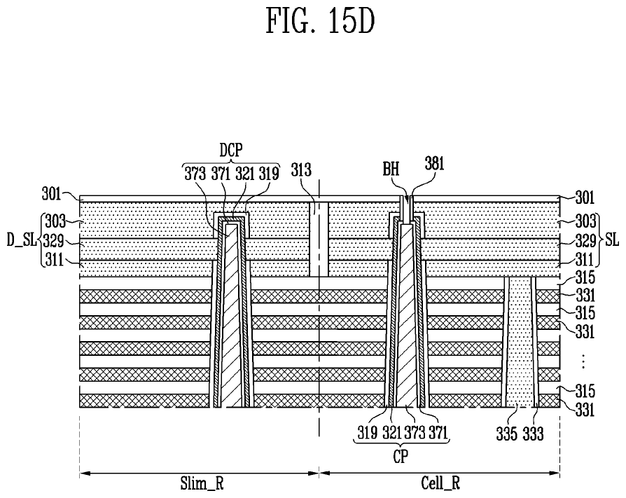

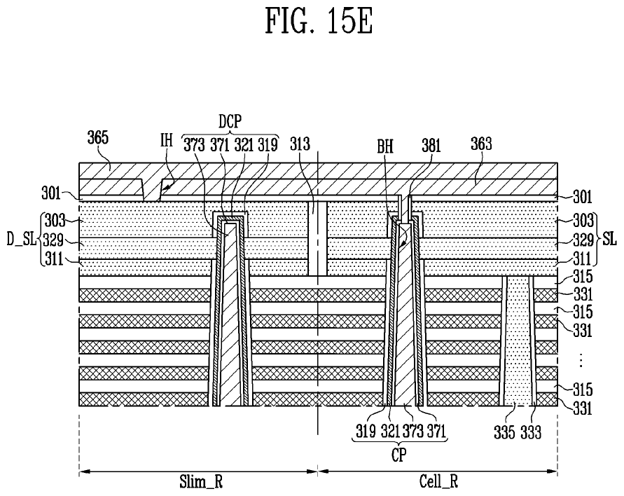

FIGS. 15A to 15E are cross-sectional views illustrating another method of manufacturing a semiconductor memory device according to the present disclosure.

FIGS. 15A to 15E are views illustrating a method of forming the backgate line connected to the backgate after the wafer bonding process, after forming the backgate in the channel plug.

In the present embodiment, before performing the wafer bonding process, the channel plug may be formed on the first substrate, and the backgate may be formed in the channel plug.

For example, as shown in FIG. 11A, the protective layer 301 is formed on the first substrate 300 defined as the cell region Cell_R and the slimming region Slim_R, and the first source layer 303, the source sacrificial layers 305, 307, and 309, and the second source layer 311 are formed on the protective layer 301. The isolation structure 313 passing through the first source layer 303, the source sacrificial layers 305, 307, and 309, and the second source layer 311 may be formed at the boundary region between the cell region Cell_R and the slimming region Slim_R. The isolation structure 313 separates the first source layer 303 and the source sacrificial layers 305, 307, and 309 of the cell region Cell_R from the first source layer 303 and the source sacrificial layers 305, 307, and 309 of the slimming region Slim_R.

Referring to FIG. 15A, the hole H extending into the first source layer 303 by passing through the stack ST of the cell region Cell_R is formed. For example, the hole H may extend into the first source layer 303 by passing through the stack ST, the second source layer 311, and the source sacrificial layers 305, 307, and 309 in the cell region Cell_R. During a process of forming the hole H, the dummy hole DH extending into the first source layer 303 by passing through the stack ST of the slimming region Slim_R may be formed together.

Thereafter, the memory layer 319 is formed on the sidewall and the bottom surface of the hole H and the dummy hole DH. The memory layer 319 may include at least one of the tunneling layer, the data storage layer, or the blocking layer. The data storage layer may include a floating gate, a charge trap material, polysilicon, nitride, a variable resistance material, a nano structure, or a combination thereof. Thereafter, the channel layer 321 is formed along a surface of the memory layer 319. The channel layer 321 may include a semiconductor material such as silicon or germanium. Thereafter, a first backgate insulating layer 371 is formed along a surface of the channel layer 321. The first backgate insulating layer 371 may include an oxide material. Thereafter, a backgate 373 may be formed to completely fill the central region of the hole H and the dummy hole DH. The backgate 373 may be formed of a conductive material such as a polysilicon layer or a tungsten layer. Thereafter, a recess region is formed by etching a portion of an upper end portion of the first backgate insulating layer 371 and the backgate 373, and a second backgate insulating layer 375 is formed to cover the upper end portion of the backgate 373. Thereafter, the capping layer 325 filling the recess region is formed on the second backgate insulating layer 375. The capping layer 325 may include a conductive material and may be directly connected to the channel layer 321.

The memory layer 319, the channel layer 321, the first and second backgate insulating layers 371 and 375, the backgate 373, and the capping layer 325 formed in the hole H of the cell region Cell_R may be defined as the channel plug CP, and the memory layer 319, the channel layer 321, the first and second backgate insulating layers 371 and 375, the backgate 373, and the capping layer 325 formed in the dummy hole DH of the slimming region Slim_R may be defined as the dummy channel plug DCP. The dummy channel plug DCP may be used as a support for preventing the stack ST from collapsing in a subsequent process.

Referring to FIG. 15B, the source sacrificial layer is exposed by forming the trench TR passing through the stack ST and the second source layer 311 of the cell region Cell_R, and the sacrificial spacer 327 is formed on the sidewall of the trench TR. In the above-described process, a process of exposing the source sacrificial layer by forming the dummy trench DTR passing through the stack ST and the second source layer 311 of the slimming region Slim_R and forming the sacrificial spacer 327 on the sidewall of the dummy trench D_TR may be performed together.

Thereafter, the source sacrificial layer exposed by the trench TR and the source sacrificial layer exposed by the dummy trench D_TR are removed. A sidewall of the channel plug CP and the sidewall of the dummy channel plug DCP, that is, a portion of the memory layer 319 is exposed by a space from which the source sacrificial layer is removed. Thereafter, a portion of the channel layer 321 is exposed by etching a portion of the exposed memory layer 319.

Thereafter, the third source layer 329 is formed in the space from which the source sacrificial layer is removed. The third source layer 329 may be formed of polysilicon doped with a dopant. Accordingly, the source lines SL 303, 311, and 329 connected to a partial sidewall of the channel layer 321 are formed in the cell region Cell_R, and the dummy source lines D_SL 303, 311, and 329 connected to a partial sidewall of the channel layer 321 are formed in the slimming region Slim_R.

Thereafter, the process of forming the wiring and the first connection structures is performed with reference to FIGS. 11D and 11E described above, and the process of forming the CMOS circuit and the second connection structures on the second substrate described with reference to FIG. 5 and the wafer bonding process of bonding the first connection structures and the second connection structures each other described with reference to FIG. 12 may be performed. A description thereof is omitted.

Referring to FIG. 15C, the first substrate 300 shown in FIG. 15B is removed. Accordingly, the protective layer 301 is exposed.

Referring to FIG. 15D, the backgate hole BH exposing an upper surface of the memory layer 319 by passing through the protective layer 301 and the first source layer 303 of the cell region Cell_R is formed by performing an etching process using a mask. The backgate hole BH may be formed to overlap the channel plug CP including the memory layer 319, the channel layer 321, the first backgate insulating layer 371, and the backgate 373.

Thereafter, the backgate 373 is exposed by sequentially etching the memory layer 319, the channel layer 321, and the first backgate insulating layer 371 exposed through the backgate hole BH.

Thereafter, a third backgate insulating layer 381 covering the sidewall of the backgate hole BH including an exposed surface of the first source layer 303, an exposed surface of the memory layer 319, and a surface of the channel layer 321. The third backgate insulating layer 381 may be formed of an oxide layer.

Referring to FIG. 15E, a first conductive layer for backgate line 363 is formed by forming a conductive material inside the backgate hole BH and on the entire structure. The first conductive layer for backgate line 363 may be formed of a doped polysilicon layer or a metal material layer. The third backgate insulating layer 381 electrically and physically separates the first conductive layer for backgate line 363 from the channel layer 321. The third backgate insulating layer 381 electrically and physically separates the first conductive layer for backgate line 363 from the memory layer 319. In addition, the backgate insulating layer 361 electrically and physically separates the first conductive layer for backgate line 363 from the first source layer 303.

Thereafter, an interconnection hole IH exposing the dummy source line D_SL by passing through the conductive layer for backgate line 363 and the protective layer 301 of the slimming region Slim_R is formed by performing an etching process using a mask. Because the interconnection hole IH is formed to expose a portion of the dummy source line D_SL of the slimming region Slim_R, securing a process margin is possible.

Thereafter, a second conductive layer for backgate line 365 is formed by forming a conductive material inside the interconnection hole IH and on the entire structure. The second conductive layer for backgate line 365 electrically connects the first conductive layer for backgate line 363 and the channel layer 321 of the dummy channel plug DCP.

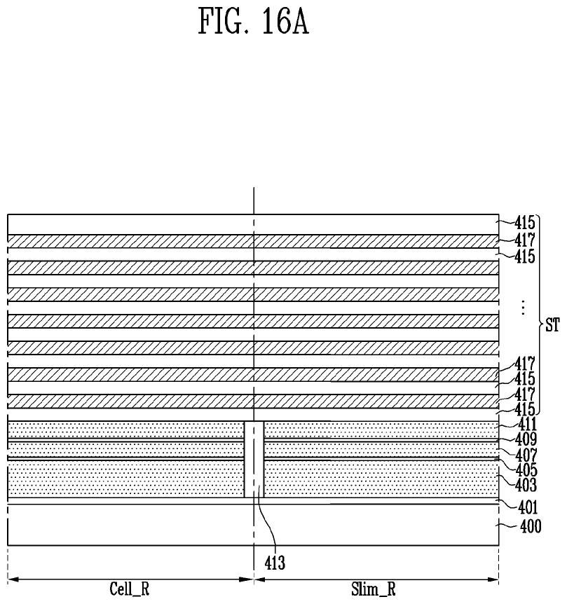

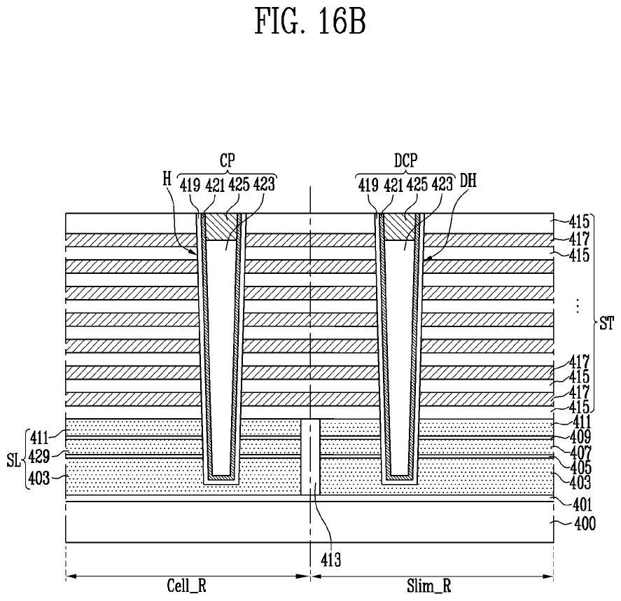

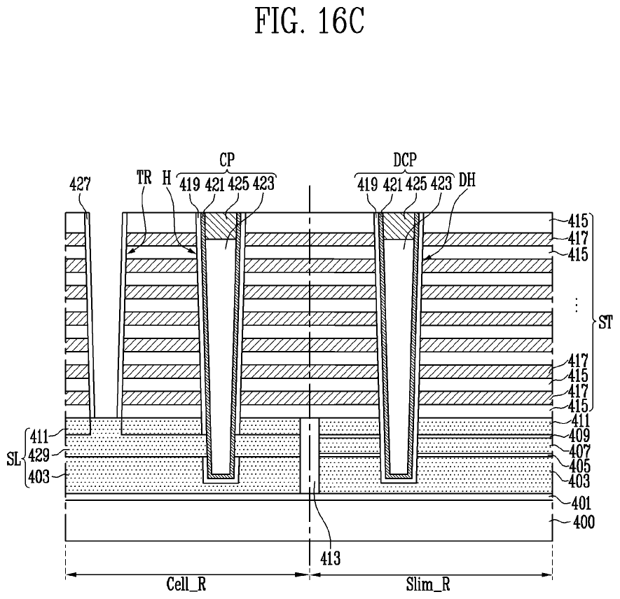

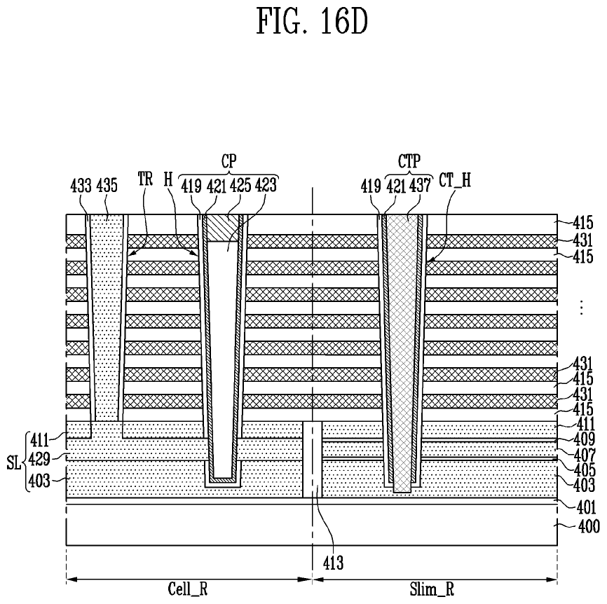

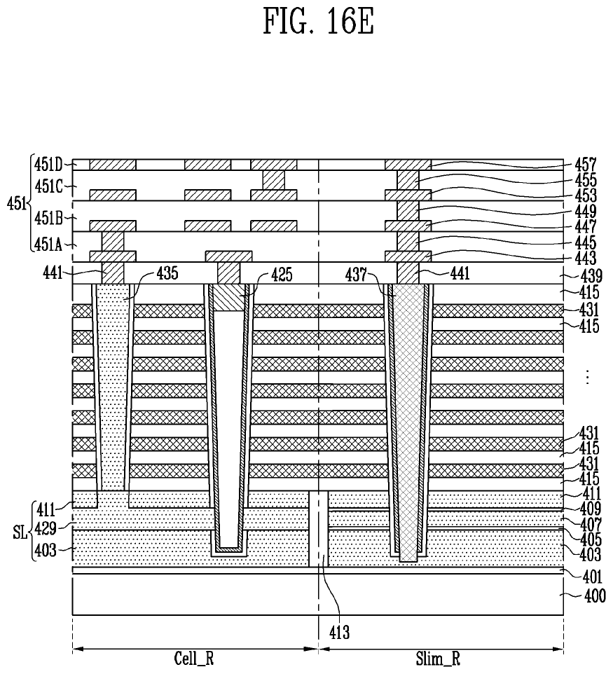

FIGS. 16A to 16E, 17, and 18A to 18C are cross-sectional views illustrating another method of manufacturing a semiconductor memory device according to the present disclosure.

FIGS. 16A to 16E are cross-sectional views illustrating a step of forming the memory cell array, the first wiring array, and the first connection structures on the first substrate.

Referring to FIG. 16A, a protective layer 401 is formed on a first substrate 400 defined as the cell region Cell_R and the slimming region Slim_R. The protective layer 401 may be formed of a nitride layer or an oxide layer. The first substrate 400 may be a sacrificial substrate. The cell region Cell_R may be a region in which memory cells are formed, and the slimming region Slim_R may be a region disposed adjacent to the cell region Cell_R and may be defined as a region in which a gate electrode connected to the memory cells is extended and disposed.

Thereafter, a first source layer 403, source sacrificial layers 405, 407, and 409, and a second source layer 411 are formed on the protective layer 401. The first source layer 403 and the second source layer 411 may include a polysilicon layer. The first source layer 403 and the second source layer 411 may include an N-type or P-type impurity. The source sacrificial layers 405, 407, and 409 may include a first source sacrificial layer 405, a second source sacrificial layer 407, and a third source sacrificial layer 409. As another example, differently from that shown, the source sacrificial layer may be configured of a single layer. Hereinafter, the source sacrificial layer is described as including the first to third source sacrificial layers 405, 407, and 409, but a structure of the source sacrificial layer might not be limited thereto. For example, the first source sacrificial layer 405 may include an oxide or a high dielectric constant (high-k) material. For example, the high dielectric constant material may include Al₂O₃. For example, the second source sacrificial layer 407 may include polysilicon. For example, the third source sacrificial layer 409 may include an oxide or a high dielectric constant (high-k) material.

Thereafter, an isolation structure 413 passing through the first source layer 403, the source sacrificial layers 405, 407, and 409, and the second source layer 411 formed on the boundary between the cell region Cell_R and the slimming region Slim_R is formed. The isolation structure 413 separates the first source layer 403 and the source sacrificial layers 405, 407, and 409 of the cell region Cell_R, and the first source layer 403 and the source sacrificial layers 405, 407, and 409 of the slimming region Slim_R from each other. The isolation structure 413 may be formed of an insulating material such as an oxide layer or a nitride layer.

Thereafter, the stack ST is formed on the source sacrificial layers 405, 407, and 409 of the cell region Cell_R and the source sacrificial layers 405, 407, and 409 of the slimming region Slim_R. The stack ST may include first material layers 415 and second material layers 417 that are alternately stacked. The second material layers 417 may be for forming a gate electrode of a memory cell, a select transistor, and the like, and the first material layers 415 may be for insulating stacked gate electrodes from each other. The second material layers 417 are formed of a material having a high etch selectivity with respect to the first material layers 415. For example, the first material layers 415 may be insulating layers including an oxide or the like, and the second material layers 417 may be sacrificial layers including nitride or the like. As another example, the first material layers 415 may be insulating layers including an oxide or the like, and the second material layers 417 may be conductive layers including polysilicon, tungsten, or the like.

Referring to FIG. 16B, a hole H extending into the first source layer 403 by passing through the stack ST of the cell region Cell_R is formed. For example, the hole H may extend into the first source layer 403 by passing through the stack ST, the second source layer 411, and the source sacrificial layers 405, 407, and 409 in the cell region Cell_R. During a process of forming the hole H, the dummy hole DH extending into the first source layer 403 by passing through the stack ST of the slimming region Slim_R may be formed together.

Thereafter, a memory layer 419 is formed on the sidewall and the bottom surface of the hole H and the dummy hole DH. The memory layer 419 may include at least one of a tunneling layer, a data storage layer, or a blocking layer. The data storage layer may include a floating gate, a charge trap material, polysilicon, nitride, a variable resistance material, a nano structure, or a combination thereof. Thereafter, a channel layer 421 is formed along a surface of the memory layer 419. The channel layer 421 may include a semiconductor material such as silicon or germanium. Thereafter, a backgate sacrificial layer 423 may be formed to completely fill the central region of the hole H and the dummy hole DH. The backgate sacrificial layer 423 may be formed of an oxide layer. Thereafter, a recess region is formed by etching a portion of an upper end portion of the backgate sacrificial layer 423, and a capping layer 425 is formed in the recess region. The capping layer 425 may include a conductive material and may be directly connected to the channel layer 421. A lower surface height of the capping layer 425 may be equal to or lower than that of an upper surface of the second material layer 417 disposed at the uppermost portion of the plurality of second material layers 417. The memory layer 419, the channel layer 421, the backgate sacrificial layer 423, and the capping layer 425 formed in the hole H of the cell region Cell_R may be defined as the preliminary channel plug CP, the memory layer 419, the channel layer 421, the backgate sacrificial layer 423, and the capping layer 425 formed in the dummy hole DH of the slimming region Slim_R may be defined as the dummy channel plug DCP. The dummy channel plug DCP may be used as a support for preventing the stack ST from collapsing in a subsequent process.

Referring to FIG. 16C, the source sacrificial layer is exposed by forming a trench TR passing through the stack ST of the cell region Cell_R and the second source layer 411, and a sacrificial spacer 427 is formed on a sidewall of the trench TR. Thereafter, the source sacrificial layer exposed by the trench TR is removed. A sidewall of the preliminary channel plug CP, that is, a portion of the memory layer 419 is exposed by a space from which the source sacrificial layer is removed. Thereafter, a portion of the channel layer 421 is exposed by etching a portion of the exposed memory layer 419.

Thereafter, a third source layer 429 is formed in a space from which the source sacrificial layer is removed. The third source layer 429 may be formed of polysilicon doped with a dopant. Accordingly, the source lines SL 403, 411, and 429 connected to a partial sidewall of the channel layer 421 are formed.

Referring to FIG. 16D, a sidewall of the second material layers 417 of FIG. 16 is exposed by removing the sacrificial spacer 427 of FIG. 16C. Thereafter, a recess region is formed by removing the second material layers 417 of FIG. 16C of the cell region Cell_R and the slimming region Slim_R exposed by the trench TR, and gate patterns 431 are formed by filling the recess region with a conductive material. Thereafter, after forming a spacer layer 433 on the sidewall of the trench TR, and a wiring 435 connected to the source lines SL 403, 411, and 429 is formed by filling the trench TR with a conductive material. A plurality of gate patterns 431 and a plurality of first material layers 415 may be defined as a gate stack.

Thereafter, a contact hole CT_H passing through the dummy channel plug DCP of FIG. 16C of the slimming region Slim_R is formed. The contact hole CT_H may be formed to extend into the first source layer 403 by passing through the dummy channel plug DCP of FIG. 16C.

Thereafter, a contact plug 437 may be formed by filling an inside of the contact hole CT_H with a conductive material. When the channel layer 421 is exposed on a sidewall of the contact hole CT_H, the channel layer 421 and the contact plug 437 may be defined as a contact wiring CTP. The contact plug 437 may be formed to be in contact with the first source layer 403.

Referring to FIG. 16E, an insulating layer 439 is formed on the cell region Cell_R and the slimming region Slim_R, and contacts 441 respectively connected to the wiring 435, the capping layers 425, and the contact plug 437 by passing through the insulating layer 439 are formed.

A first wiring array 443 may be formed on the insulating layer 439 of the cell region Cell_R. The first wiring array 443 may include a bit line and a source line wiring connected to the contacts 441. A second wiring array 443 may be formed on the insulating layer 439 of the slimming region Slim_R, and the second wiring array 443 may be electrically connected to the contact plug 437. Thereafter, a first insulating structure 451 covering the first and second wiring arrays 443 may be formed. The first insulating structure 451 may include two or more insulating layers 451A to 451D. First connection structures 447, 453, and 457 may be buried in the first insulating structure 451, and the first connection structures 447, 453, and 457 may be electrically connected through contacts (for example, 445, 449, and 455).

The first connection structures 447, 453, and 457 may include a first bonding metal 457 having a surface exposed to an outside of the first insulating structure 451.

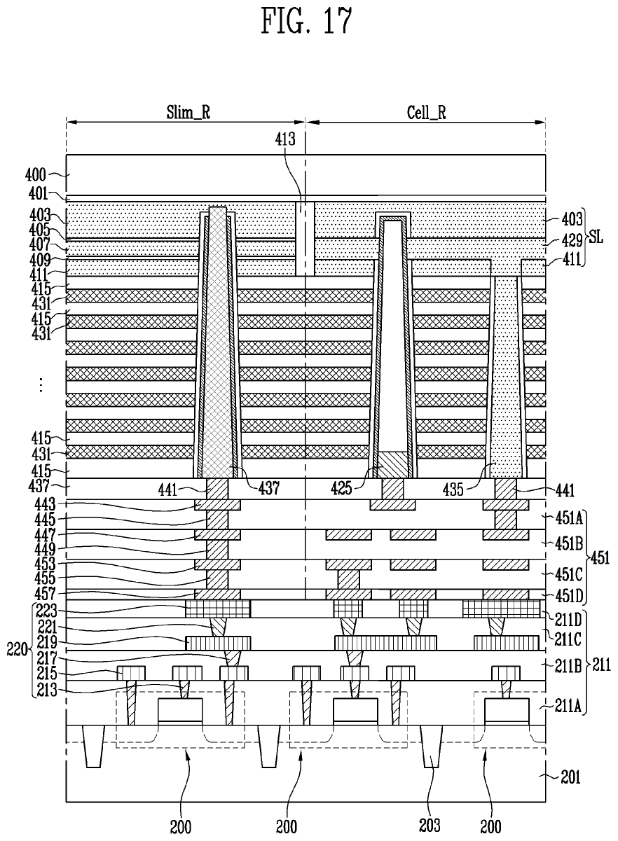

FIG. 17 is a cross-sectional view illustrating a step of bonding the first connection structures and the second connection structures to each other.

Referring to FIG. 17, the first substrate 400 and the second substrate 201 are aligned so that the first bonding metal 457 on the first substrate 400 and the second bonding metal 223 of the second substrate 201 on which the CMOS circuit and the second connection structures described with reference to FIG. 5 are formed. The first bonding metal 457 and the second bonding metal 223 may include various metals, for example, copper.

Thereafter, the first bonding metal 457 and the second bonding metal 223 are bonded to each other. To this end, after heat is applied to the first bonding metal 457 and the second bonding metal 223, the first bonding metal 457 and the second bonding metal 223 may be cured. The present disclosure is not limited thereto, and various processes for connecting the first bonding metal 457 and the second bonding metal 223 may be introduced.

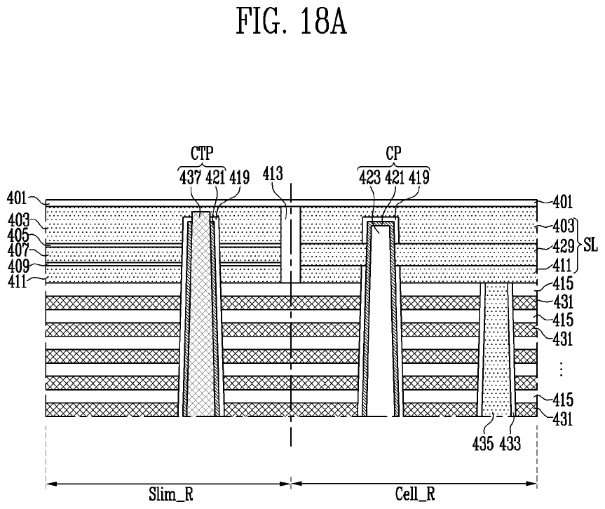

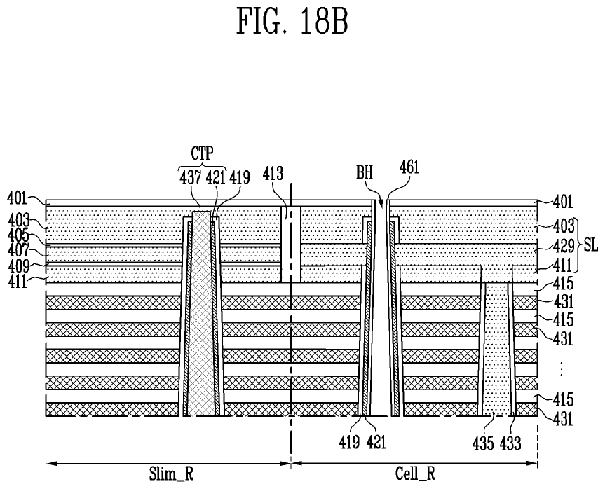

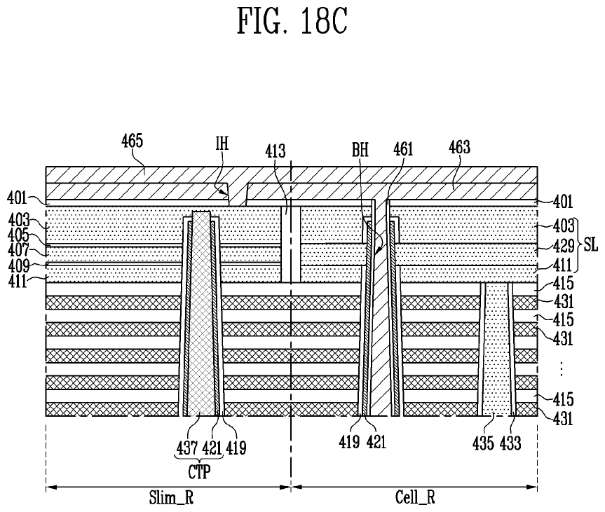

FIGS. 18A to 18C are cross-sectional views illustrating a step of forming the backgate in the preliminary channel plug of the cell region Cell_R and forming the backgate line structure connected to the backgate.

Referring to FIG. 18A, the first substrate 400 shown in FIG. 17 is removed. Accordingly, the protective layer 401 is exposed.

Referring to FIG. 18B, the backgate hole BH exposing an upper surface of the memory layer 419 by passing through the protective layer 401 and the first source layer 403 of the cell region Cell_R is formed by performing an etching process using a mask. The backgate hole BH may be formed to overlap the preliminary channel plug including the memory layer 419, the channel layer 421, and the backgate sacrificial layer.

Thereafter, the backgate sacrificial layer is exposed by sequentially etching the memory layer 419 and the channel layer 421 exposed through the backgate hole BH, and the exposed backgate sacrificial layer is removed.

A backgate insulating layer 461 covering the side of the backgate hole BH including an exposed surface of the first source layer 403, an exposed surface of the memory layer 419, and a surface of the channel layer 421 exposed by removing the backgate sacrificial layer is formed. The backgate insulating layer 461 may be formed of an oxide layer.

Referring to FIG. 18C, a backgate structure layer 463 is formed by forming a conductive material inside the backgate hole BH and on the entire structure. The backgate structure layer 463 may be formed of a doped polysilicon layer or a metal material layer. The memory layer 419, the channel layer 421, the backgate insulating layer 461, and the backgate structure layer 463 may be defined as the channel plug. The backgate insulating layer 461 electrically and physically separates the backgate structure layer 463 from the channel layer 421. The backgate insulating layer 461 electrically and physically separates the backgate structure layer 463 from the memory layer 419. In addition, the backgate insulating layer 461 electrically and physically separates the backgate structure layer 463 from the first source layer 403.

Thereafter, an interconnection hole IH exposing a portion of the first source layer 403 by passing through the backgate structure layer 463 and the protective layer 401 of the slimming region Slim_R is formed by performing an etching process using a mask.

Thereafter, a backgate line layer 465 is formed by forming a conductive material inside the interconnection hole IH and on the entire structure. The backgate line layer 465 and the first source layer 403 electrically connect the backgate structure layer 463 and the contact plug 437.

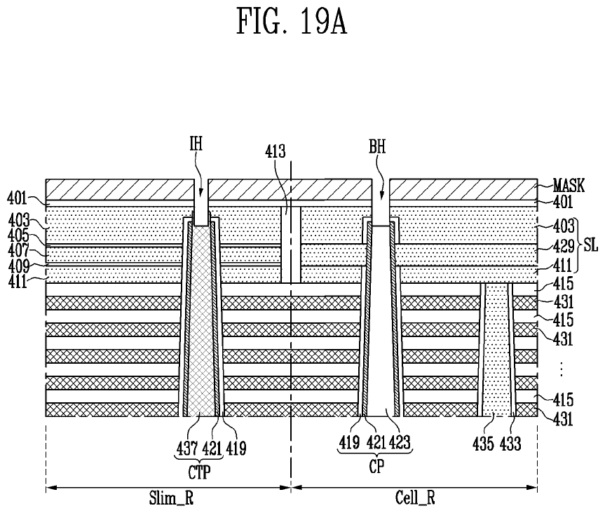

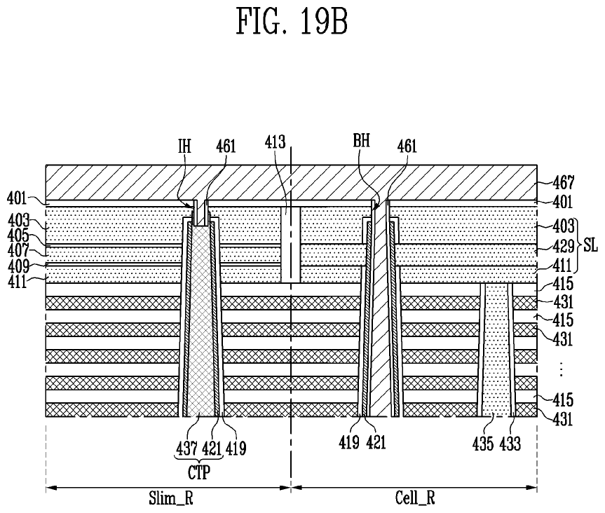

FIGS. 19A and 19B are cross-sectional views illustrating another method of manufacturing a semiconductor memory device according to the present disclosure.

Referring to FIG. 19A, the first substrate 400 shown in FIG. 17 is removed, and a mask pattern MASK is formed on the protective layer 401. The mask pattern MASK may be formed so that a region overlapping the preliminary channel plug CP of the cell region Cell_R is opened and a partial region of the slimming region Slim_R is opened.

Thereafter, the backgate hole BH exposing the backgate sacrificial layer 423 of the cell region Cell_R and the interconnection hole IH exposing the first source layer 403 or the contact plug 437 are formed by performing an etching process using the mask pattern MASK.

Referring to FIG. 19B, the mask pattern MASK of FIG. 19A and the backgate sacrificial layer 423 of FIG. 19A are removed. The backgate insulating layer 461 covering the side of the backgate hole BH including an exposed surface of the first source layer 403, an exposed surface of the memory layer 419, and a surface of the channel layer 421 exposed by removing the backgate sacrificial layer is formed. The backgate insulating layer 461 may be formed of an oxide layer.

Thereafter, a backgate structure layer 467 is formed by forming a conductive material inside the backgate hole BH, inside the interconnection hole IH, and on the entire structure. The backgate structure layer 467 may be formed of a doped polysilicon layer or a metal material layer. The memory layer 419, the channel layer 421, the backgate insulating layer 461, and the backgate structure layer 467 may be defined as the channel plug. The backgate insulating layer 461 electrically and physically separates the backgate structure layer 467 from the channel layer 421. The backgate insulating layer 461 electrically and physically separates the backgate structure layer 467 from the memory layer 419. In addition, the backgate insulating layer 461 electrically and physically separates the backgate structure layer 467 from the first source layer 403.

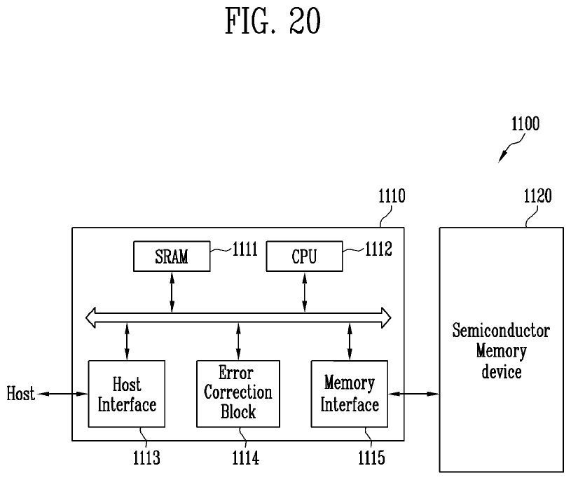

FIG. 20 is a block diagram illustrating a configuration of a memory system 1100 according to an embodiment of the present disclosure.

Referring to FIG. 20, the memory system 1100 includes a semiconductor memory device 1120 and a memory controller 1110.

The semiconductor memory device 1120 may be a multi-chip package configured of a plurality of flash memory chips. The semiconductor memory device 1120 may be the semiconductor memory device described with reference to FIGS. 1 to 3.

The memory controller 1110 may be configured to control the semiconductor memory device 1120, and may include static random access memory (SRAM) 1111, a central processing unit (CPU) 1112, a host interface 1113, an error correction block 1114, and a memory interface 1115. The SRAM 1111 is used as operation memory of the CPU 1112, the CPU 1112 performs overall control operations for data exchange of the memory controller 1110, and the host interface 1113 includes a data exchange protocol of a host connected to the memory system 1100. In addition, the error correction block 1114 detects and corrects errors included in data read from the semiconductor memory device 1120, and the memory interface 1115 performs interfacing with the semiconductor memory device 1120. In addition, the memory controller 1110 may further include read only memory (ROM) that stores code data for interfacing with the host.

The above-described memory system 1100 may be a memory card or a solid state disk (SSD) in which the semiconductor memory device 1120 and the memory controller 1110 are combined. For example, when the memory system 1100 is the SSD, the memory controller 1110 may communicate with an outside (for example, a host) through one of various interface protocols such as a universal serial bus (USB), a multi-media card (MMC), a peripheral component interconnection-express (PCI-E), a serial advanced technology attachment (SATA), a parallel advanced technology attachment (PATA), a small computer system interface (SCSI), an enhanced small disk interface (ESD), and integrated drive electronics (IDE).

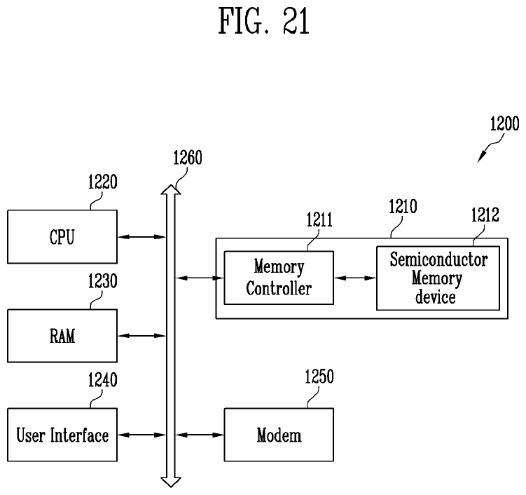

FIG. 21 is a block diagram illustrating a configuration of a computing system according to an embodiment.

Referring to FIG. 21, the computing system 1200 according to an embodiment or the present disclosure may include a CPU 1220, random access memory (RAM) 1230, a user interface 1240, a modem 1250, and a memory system 1210 electrically connected to a system bus 1260. In addition, when the computing system 1200 is a mobile device, a battery for supplying an operation voltage to the computing system 1200 may be further included, and an application chipset, a camera image processor (CIS), mobile DRAM, and the like may be further included.

Although the detailed description of the present disclosure describes specific embodiments and methods, various changes and modifications are possible without departing from the scope and technical spirit of the present disclosure. Therefore, the scope of the present disclosure should not be limited to the above-described embodiments and methods, and should be determined by the equivalents of the claims of the present disclosure as well as the following claims.

What is claimed is:

1. A semiconductor memory device comprising:
a gate stack including a plurality of gate patterns and a plurality of interlayer insulating layers alternately stacked with each other in a cell region;
a source line disposed on the gate stack; and
a channel plug passing through the gate stack and the source line in a vertical direction,
wherein the channel plug comprises:
a backgate;
a backgate insulating layer surrounding a sidewall of the backgate;
a channel layer surrounding the sidewall of the backgate; and
a memory layer surrounding a sidewall of the channel layer, and
wherein the backgate insulating layer extends between the backgate and the source line.

2. The semiconductor memory device of claim 1, further comprising:
a protective layer disposed on the source line; and
a backgate line structure disposed on the protective layer,
wherein the backgate line structure is electrically connected to the backgate.

3. The semiconductor memory device of claim 1, wherein the source line is directly connected to a portion of the sidewall of the channel layer.

4. The semiconductor memory device of claim 1, further comprising:
a wiring passing through the gate stack and connected to the source line.

5. The semiconductor memory device of claim 2, further comprising:
a stack including the plurality of interlayer insulating layers and a plurality of sacrificial layers alternately stacked in a contact region;
a buffer insulating layer disposed on the stack; and
a contact plug passing through the stack and the buffer insulating layer in the vertical direction.

6. The semiconductor memory device of claim 5, wherein the backgate line structure is electrically spaced apart from the contact plug.

7. A method of manufacturing a semiconductor memory device, the method comprising:
sequentially stacking a protective layer, a first source layer, a sacrificial layer, and a second source layer in a cell region of a first substrate;
forming a stack in which a plurality of first material layers and a plurality of second material layers are alternately stacked on the second source layer;
forming a preliminary channel plug passing through the stack, the second source layer, and the sacrificial layer;
forming a trench passing through the stack and the second source layer to expose the sacrificial layer;
exposing a portion of a sidewall of the preliminary channel plug by removing the exposed sacrificial layer;
forming a third source layer in a space from which the sacrificial layer is removed; and
removing the plurality of second material layers exposed through the trench, and forming a plurality of gate patterns in a space from which the plurality of second material layers are removed,
wherein forming the preliminary channel plug comprises:
forming a hole passing through the stack, the second source layer, and the sacrificial layer; and
sequentially forming a memory layer and a channel layer along a sidewall and a bottom surface of the hole, and then forming a backgate sacrificial layer in a central region of the hole.

8. The method of claim 7, further comprising:
forming a first connection structure on the stack;
forming a complementary metal oxide semiconductor (CMOS) circuit on a second substrate;
forming a second conductive connection structure connected to the CMOS circuit on the second substrate; and
bonding a first bonding metal of the first connection structure and a second bonding metal of the second connection structure to each other so that the first connection structure and the second connection structure are connected to each other.

9. The method of claim 8, further comprising:
after bonding the first bonding metal and the second bonding metal to each other, removing the first substrate;
exposing the backgate sacrificial layer by forming a backgate hole passing through the protective layer, the first source layer, the memory layer, and the channel layer;
expanding the backgate hole by removing the backgate sacrificial layer;
forming a backgate insulating layer along a sidewall of the channel layer, a sidewall of the memory layer, and a sidewall of the first source layer; and
forming a backgate structure layer by forming a conductive material inside the backgate hole and on an entire structure.

10. The method of claim 9, further comprising:
forming the protective layer, a buffer insulating layer, and the stack in a contact region of the first substrate; and
forming a contact plug passing through the stack, the buffer insulating layer, and the protective layer.

11. The method of claim 10, further comprising:
after forming the backgate structure layer, separating the backgate structure layer of the cell region and the backgate structure layer of the contact region from each other by patterning the backgate structure layer.

12. The method of claim 8, further comprising:
after bonding the first bonding metal and the second bonding metal to each other, removing the first substrate and the protective layer;
etching the first source layer resulting in a protruding preliminary channel plug;
exposing the backgate sacrificial layer by etching the memory layer and the channel layer of the protruding preliminary channel plug, and forming a backgate hole by removing the exposed backgate sacrificial layer;
forming a backgate insulating layer along a sidewall of the backgate hole and an upper surface of the first source layer; and
forming a backgate structure layer by forming a conductive material inside the backgate hole and on an entire structure.

13. A method of manufacturing a semiconductor memory device, the method comprising:
sequentially stacking a protective layer, a first source layer, a sacrificial layer, and a second source layer in a cell region of a first substrate;
forming a stack in which a plurality of first material layers and a plurality of second material layers are alternately stacked on the second source layer;
forming a channel plug passing through the stack, the second source layer, and the sacrificial layer;
forming a trench passing through the stack and the second source layer to expose the sacrificial layer;
exposing a portion of a sidewall of the channel plug by removing the exposed sacrificial layer;
forming a third source layer in a space from which the sacrificial layer is removed; and
removing the plurality of material layers exposed through the trench, and forming a plurality of gate patterns in a space from which the plurality of material layers are removed,
wherein forming the channel plug comprises:
forming a hole passing through the stack, the second source layer, and the sacrificial layer; and
sequentially forming a memory layer, a channel layer, and a first backgate insulating layer along a sidewall and a bottom surface of the hole, and then forming a backgate in a central region of the hole.

14. The method of claim 13, further comprising:
forming a first connection structure on the stack;
forming a complementary metal oxide semiconductor (CMOS) circuit on a second substrate;
forming a second conductive connection structure connected to the CMOS circuit on the second substrate; and
bonding a first bonding metal of the first connection structure and a second bonding metal of the second connection structure to each other so that the first connection structure and the second connection structure are connected to each other.

15. The method of claim 14, further comprising:
after bonding the first bonding metal and the second bonding metal to each other, removing the first substrate;
exposing the backgate by forming a backgate hole passing through the protective layer, the first source layer, the memory layer, the channel layer, and the first backgate insulating layer;
forming a second backgate insulating layer on a sidewall of the backgate hole; and
forming a backgate structure layer by forming a conductive material inside the backgate hole and on an entire structure.

16. The method of claim 15, further comprising:
forming the protective layer, a buffer insulating layer, and the stack in a contact region of the first substrate; and
forming a contact plug passing through the stack, the buffer insulating layer, and the protective layer.

17. The method of claim 16, further comprising:
after forming the backgate structure layer, separating the backgate structure layer of the cell region and the backgate structure layer of the contact region from each other by patterning the backgate structure layer.

18. The method of claim 14, further comprising:
after bonding the first bonding metal and the second bonding metal to each other, removing the first substrate and the protective layer;
etching the first source layer resulting in a protruding preliminary channel plug;
exposing the backgate by etching the memory layer and the channel layer of the protruding channel plug, and the first backgate insulating layer;
forming a second backgate insulating layer along exposed surfaces of the first source layer, the memory layer, and the channel layer; and
forming a backgate structure layer connected to the backgate on the second backgate insulating layer.

19. A semiconductor memory device comprising:
a gate stack including a plurality of gate patterns and a plurality of interlayer insulating layers alternately stacked with each other in a cell region and a slimming region;
a source line disposed on the gate stack of the cell region;
a sacrificial pattern including a first source layer, a sacrificial layer, and a second source layer disposed on the gate stack of the slimming region;
a separation pattern separating the source line from the sacrificial pattern in a boundary region between the cell region and the slimming region; and
a channel plug passing through the gate stack of the cell region and a backgate connection structure passing through the gate stack of the slimming region.

20. The semiconductor memory device of claim 19, wherein the channel plug comprises:
a backgate;
a backgate insulating layer surrounding a sidewall of the backgate;
a channel layer surrounding the sidewall of the backgate; and
a memory layer surrounding a sidewall of the channel layer, and
the backgate insulating layer extends between the backgate and the source line.

21. The semiconductor memory device of claim 20, wherein the backgate connection structure comprises:
a backgate sacrificial layer;
the channel layer surrounding a sidewall of the backgate sacrificial layer; and
the memory layer surrounding a sidewall of the channel layer.

22. The semiconductor memory device of claim 21, further comprising:
a protective layer disposed on the source line and the sacrificial pattern; and
a backgate line structure disposed on the protective layer,
wherein the backgate line structure electrically connects the backgate of the channel plug and the channel layer of the backgate connection structure.

23. The semiconductor memory device of claim 20, wherein the source line is directly connected to a portion of the sidewall of the channel layer of the channel plug.

24. The semiconductor memory device of claim 19, further comprising:
a wiring passing through the gate stack and connected to the source line.

25. A method of manufacturing a semiconductor memory device, the method comprising:
sequentially stacking a protective layer, a first source layer, a sacrificial layer, and a second source layer in a cell region and a slimming region of a first substrate;
forming an isolation structure passing through the first source layer, the sacrificial layer, and the second source layer at a boundary between the cell region and the slimming region;
forming a stack in which a plurality of first material layers and a plurality of second material layers are alternately stacked with each other on the second source layer;
forming a preliminary channel plug passing through the stack, the second source layer, and the sacrificial layer of the cell region, and forming a dummy channel plug passing through the stack, the second source layer, and the sacrificial layer of the slimming region;
forming a trench passing through the stack and the second source layer of the cell region to expose the sacrificial layer;
exposing a portion of a sidewall of the preliminary channel plug by removing the exposed sacrificial layer;
forming a third source layer in a space from which the sacrificial layer is removed; and
removing the plurality of second material layers exposed through the trench, and forming a plurality of gate patterns in a space from which the plurality of second material layers are removed,
wherein forming the preliminary channel plug and the dummy channel plug comprises:
forming a hole and a dummy hole passing through the stack, the second source layer, and the sacrificial layer of the cell region and the slimming region; and
sequentially forming a memory layer and a channel layer along a sidewall and a bottom surface of the hole and the dummy hole, and then forming a backgate sacrificial layer in a central region of the hole.

26. The method of claim 25, further comprising:
forming a first connection structure on the stack;
forming a complementary metal oxide semiconductor (CMOS) circuit on a second substrate;
forming a second conductive connection structure connected to the CMOS circuit on the second substrate; and
bonding a first bonding metal of the first connection structure and a second bonding metal of the second connection structure to each other so that the first connection structure and the second connection structure are connected to each other.

27. The method of claim 26, further comprising:
after bonding the first bonding metal and the second bonding metal to each other, removing the first substrate;
exposing the backgate sacrificial layer by forming a backgate hole passing through the protective layer, the first source layer, the memory layer, and the channel layer of the cell region;
expanding the backgate hole by removing the backgate sacrificial layer;
forming a backgate insulating layer along a sidewall of the channel layer, a sidewall of the memory layer, and a sidewall of the first source layer; and
forming a first backgate structure layer by forming a conductive material inside the backgate hole and on an entire structure.

28. The method of claim 27, further comprising:
forming an interconnection hole exposing the channel layer of the dummy channel plug by etching the first backgate structure layer, the protective layer, and the memory layer of the slimming region; and
forming a second backgate structure layer connecting the first backgate structure layer and the channel layer of the dummy channel plug, by filling the interconnection hole with a conductive material.

29. A method of manufacturing a semiconductor memory device, the method comprising:
sequentially stacking a protective layer, a first source layer, a sacrificial layer, and a second source layer in a cell region and a slimming region of a first substrate;
forming an isolation structure passing through the first source layer, the sacrificial layer, and the second source layer at a boundary between the cell region and the slimming region;
forming a stack in which a plurality of first material layers and a plurality of second material layers are alternately stacked with each other on the second source layer;
forming a preliminary channel plug passing through the stack, the second source layer, and the sacrificial layer of the cell region, and forming a dummy channel plug passing through the stack, the second source layer, and the sacrificial layer of the slimming region;
forming a trench passing through the stack and the second source layer of the cell region to expose the sacrificial layer and forming a dummy trench passing through the stack and the second source layer of the slimming region to expose the sacrificial layer;
exposing a portion of a sidewall of the preliminary channel plug and a portion of a sidewall of the dummy channel plug by removing the sacrificial layer of the cell region exposed through the trench and the sacrificial layer of the slimming region exposed through the dummy trench;
forming a source line in the cell region and a dummy source line in the slimming region by forming a third source layer in a space from which the sacrificial layer is removed; and
removing the plurality of second material layers exposed through the trench and the dummy trench, and forming a plurality of gate patterns in a space from which the plurality of second material layers are removed,
wherein forming the preliminary channel plug and the dummy channel plug comprises:
forming a hole and a dummy hole passing through the stack, the second source layer, and the sacrificial layer of the cell region and the slimming region; and
sequentially forming a memory layer and a channel layer along a sidewall and a bottom surface of the hole and the dummy hole, and then forming a backgate sacrificial layer in a central region of the hole.

30. The method of claim 29, further comprising:
forming a first connection structure on the stack;
forming a complementary metal oxide semiconductor (CMOS) circuit on a second substrate;
forming a second conductive connection structure connected to the CMOS circuit on the second substrate; and
bonding a first bonding metal of the first connection structure and a second bonding metal of the second connection structure to each other so that the first connection structure and the second connection structure are connected to each other.

31. The method of claim 30, further comprising:
after bonding the first bonding metal and the second bonding metal to each other, removing the first substrate;
exposing the backgate sacrificial layer by forming a backgate hole passing through the protective layer, the first source layer, the memory layer, and the channel layer of the cell region;
expanding the backgate hole by removing the backgate sacrificial layer;
forming a backgate insulating layer along a sidewall of the channel layer, a sidewall of the memory layer, and a sidewall of the first source layer; and
forming a first backgate structure layer by forming a conductive material inside the backgate hole and on an entire structure.

32. The method of claim 31, further comprising:
forming an interconnection hole exposing the first source layer by etching the first backgate structure layer and the protective layer of the slimming region; and
forming a second backgate structure layer connecting the first backgate structure layer and the first source layer, by filling the interconnection hole with a conductive material.

33. A method of manufacturing a semiconductor memory device, the method comprising:
sequentially stacking a protective layer, a first source layer, a sacrificial layer, and a second source layer in a cell region and a slimming region of a first substrate;
forming an isolation structure passing through the first source layer, the sacrificial layer, and the second source layer at a boundary between the cell region and the slimming region;
forming a stack in which a plurality of first material layers and a plurality of second material layers are alternately stacked with each other on the second source layer;
forming a channel plug passing through the stack, the second source layer, and the sacrificial layer of the cell region, and forming a dummy channel plug passing through the stack, the second source layer, and the sacrificial layer of the slimming region;
forming a trench passing through the stack and the second source layer of the cell region to expose the sacrificial layer and forming a dummy trench passing through the stack and the second source layer of the slimming region to expose the sacrificial layer;
exposing a portion of a sidewall of the channel plug and a portion of a sidewall of the dummy channel plug by removing the sacrificial layer of the cell region exposed through the trench and the sacrificial layer of the slimming region exposed through the dummy trench;
forming a source line in the cell region and a dummy source line in the slimming region by forming a third source layer in a space from which the sacrificial layer is removed; and
removing the plurality of second material layers exposed through the trench and the dummy trench, and forming a plurality of gate patterns in a space from which the plurality of second material layers are removed,
wherein forming the channel plug and the dummy channel plug comprises:
forming a hole and a dummy hole passing through the stack, the second source layer, and the sacrificial layer of the cell region and the slimming region; and
sequentially forming a memory layer, a channel layer, and a first backgate insulating layer along a sidewall and a bottom surface of the hole and the dummy hole, and then forming a backgate in a central region of the hole.

34. The method of claim 33, further comprising:
forming a first connection structure on the stack;
forming a complementary metal oxide semiconductor (CMOS) circuit on a second substrate;
forming a second conductive connection structure connected to the CMOS circuit on the second substrate; and
bonding a first bonding metal of the first connection structure and a second bonding metal of the second connection structure to each other so that the first connection structure and the second connection structure are connected to each other.

35. The method of claim 34, further comprising:
after bonding the first bonding metal and the second bonding metal to each other, removing the first substrate;
exposing the backgate by forming a backgate hole passing through the protective layer, the first source layer, the memory layer, the channel layer, and the first backgate insulating layer of the cell region;
forming a second backgate insulating layer on a sidewall of the backgate hole; and
forming a first backgate structure layer by forming a conductive material inside the backgate hole and on an entire structure.

36. The method of claim 35, further comprising:
forming an interconnection hole exposing the first source layer by etching the first backgate structure layer and the protective layer of the slimming region; and
forming a second backgate structure layer connecting the first backgate structure layer and the first source layer, by filling the interconnection hole with a conductive material.

37. A method of manufacturing a semiconductor memory device, the method comprising:
sequentially stacking a protective layer, a first source layer, a sacrificial layer, and a second source layer in a cell region and a slimming region of a first substrate;
forming an isolation structure passing through the first source layer, the sacrificial layer, and the second source layer at a boundary between the cell region and the slimming region;
forming a stack in which a plurality of first material layers and a plurality of second material layers are alternately stacked with each other on the second source layer;
forming a preliminary channel plug passing through the stack, the second source layer, and the sacrificial layer of the cell region, and forming a dummy channel plug passing through the stack, the second source layer, and the sacrificial layer of the slimming region is formed;
forming a trench passing through the stack and the second source layer of the cell region to expose the sacrificial layer;
exposing a portion of a sidewall of the preliminary channel plug and a portion of a sidewall of the dummy channel plug by removing the sacrificial layer of the cell region and the sacrificial layer of the slimming region exposed through the trench;
forming a source line in the cell region and a dummy source line in the slimming region by forming a third source layer in a space from which the sacrificial layer is removed;
removing the plurality of second material layers exposed through the trench, and forming a plurality of gate patterns in a space from which the plurality of second material layers are removed; and
forming a contact plug connected to the first source layer by passing through the dummy channel plug,
wherein forming the preliminary channel plug and the dummy channel plug comprises:
forming a hole and a dummy hole passing through the stack, the second source layer, and the sacrificial layer of the cell region and the slimming region; and
sequentially forming a memory layer and a channel layer along a sidewall and a bottom surface of the hole and the dummy hole, and then forming a backgate sacrificial layer in a central region of the hole.

38. The method of claim 37, further comprising:
forming a first connection structure on the stack;
forming a complementary metal oxide semiconductor (CMOS) circuit on a second substrate;
forming a second conductive connection structure connected to the CMOS circuit on the second substrate; and
bonding a first bonding metal of the first connection structure and a second bonding metal of the second connection structure to each other so that the first connection structure and the second connection structure are connected to each other.

39. The method of claim 38, further comprising:
after bonding the first bonding metal and the second bonding metal to each other, removing the first substrate;
exposing the backgate sacrificial layer by forming a backgate hole passing through the protective layer, the first source layer, the memory layer, and the channel layer of the cell region;
expanding the backgate hole by removing the backgate sacrificial layer;
forming a backgate insulating layer along a sidewall of the channel layer, a sidewall of the memory layer, and a sidewall of the first source layer; and
forming a first backgate structure layer by forming a conductive material inside the backgate hole and on an entire structure.

40. The method of claim 39, further comprising:
forming an interconnection hole exposing the first source layer by etching the first backgate structure layer and the protective layer of the slimming region; and
forming a second backgate structure layer connecting the first backgate structure layer and the first source layer, by filling the interconnection hole with a conductive material.

41. A method of manufacturing a semiconductor memory device, the method comprising:
sequentially stacking a protective layer, a first source layer, a sacrificial layer, and a second source layer in a cell region and a slimming region of a first substrate;
forming an isolation structure passing through the first source layer, the sacrificial layer, and the second source layer at a boundary between the cell region and the slimming region;
forming a stack in which a plurality of first material layers and a plurality of second material layers are alternately stacked with each other on the second source layer;
forming a channel plug passing through the stack, the second source layer, and the sacrificial layer of the cell region, and forming a dummy channel plug passing through the stack, the second source layer, and the sacrificial layer of the slimming region;
forming a trench passing through the stack and the second source layer of the cell region to expose the sacrificial layer;
exposing a portion of a sidewall of the channel plug by removing the sacrificial layer of the cell region exposed through the trench;
forming a source line in the cell region by forming a third source layer in a space from which the sacrificial layer is removed;
removing the plurality of second material layers exposed through the trench, and forming a plurality of gate patterns in a space from which the plurality of second material layers are removed; and
forming a contact plug connected to the first source layer by passing through the dummy channel plug,
wherein forming the channel plug and the dummy channel plug comprises:
forming a hole and a dummy hole passing through the stack, the second source layer, and the sacrificial layer of the cell region and the slimming region; and
sequentially forming a memory layer, a channel layer, and a first backgate insulating layer along a sidewall and a bottom surface of the hole and the dummy hole, and then forming a backgate in a central region of the hole.

42. The method of claim 41, further comprising:
forming a first connection structure on the stack;
forming a complementary metal oxide semiconductor (CMOS) circuit on a second substrate;
forming a second conductive connection structure connected to the CMOS circuit on the second substrate; and
bonding a first bonding metal of the first connection structure and a second bonding metal of the second connection structure to each other so that the first connection structure and the second connection structure are connected to each other.

43. The method of claim 42, further comprising:
after bonding the first bonding metal and the second bonding metal to each other, removing the first substrate;
forming a backgate hole passing through the protective layer, the first source layer, the memory layer, the channel layer, and the first backgate insulating layer of the cell region, and an interconnection hole passing through the protective layer and the first source layer of the slimming region;
forming a second backgate insulating layer on a sidewall of the backgate hole; and
forming a backgate structure layer by forming a conductive material inside the backgate hole, inside the interconnection hole, and on an entire structure.
